(19) United States
(12) Patent Application Publication
(10) Pub. No.: US 2026/0130064 A1
(43) Pub. Date: May 7, 2026

(54) DISPLAY PANEL AND ELECTRONIC DEVICE

(71) Applicant: Samsung Display Co., LTD., Yongin-si (KR)

(72) Inventors: Hosik Shin, Yongin-si (KR); Hyejin Joo, Yongin-si (KR); Myunghee Han, Yongin-si (KR); Hyungsoo Yoon, Yongin-si (KR)

(21) Appl. No.: 19/201,267

(22) Filed: May 7, 2025

(30) Foreign Application Priority Data
Nov. 1, 2024 (KR) 10-2024-0153715

(51) Int. Cl. H10K 59/124; H10H 29/41

(52) U.S. Cl. CPC H10K 59/124; H10H 29/41

(57) ABSTRACT

Provided is a display panel including a substrate including a first opening which is defined in the substrate and extends in a first direction and a second opening which is defined in the substrate and extends in a second direction crossing the first direction, and a light-emitting diode disposed on the substrate. At least one of a first width of the first opening in the second direction or a second width of the second opening in the first direction ranges from about 6 micrometers to about 8 micrometers.

This application claims priority to Korean Patent Application No. 10-2024-0153715, filed on Nov. 1, 2024, and all the benefits accruing therefrom under 35 U.S.C. § 119, the content of which in its entirety is herein incorporated by reference.

### BACKGROUND

### 1. Field

One or more embodiments relate to a display panel including a light-emitting diode, and an electronic device including the display panel.

2. Description of the Related Art With the advancement of display panels which visually display electrical signals, various display panels with excellent characteristics, such as, for example, thinness, light weight, and low power consumption, and electronic devices including such display panels have been introduced. For example, research has been actively conducted into display panels of various structures, such as, for example, flexible display panels which are foldable or rollable, or stretchable display panels, and electronic devices including the display panels.

### SUMMARY

One or more embodiments include a high-resolution stretchable display panel.

Additional aspects will be set forth in part in the description which follows and, in part, will be apparent from the description, or may be learned by practice of the presented embodiments of the disclosure.

According to one or more embodiments, a display panel includes a substrate including a first opening which is defined in the substrate and extends in a first direction and a second opening which is defined in the substrate and extends in a second direction crossing the first direction, and a light-emitting diode disposed on the substrate, wherein at least one of a first width of the first opening in the second direction or a second width of the second opening in the first direction ranges from about 6 micrometers to about 8 micrometers.

In an embodiment, the substrate may include a plurality of first openings defined in the substrate and a plurality of second openings defined in the substrate, and may further include a bridge portion between a first opening among the plurality of first openings and a second opening among the plurality of second openings.

In an embodiment, the bridge portion may include a first bridge portion which extends in the first direction and a second bridge portion which extends in the second direction, and at least one of a length of the first bridge portion in the first direction or a length of the second bridge portion in the second direction ranges from about 17 micrometers to about 25 micrometers.

In an embodiment, the substrate may include an island portion which is partially surrounded by the first opening and the second opening, and the light-emitting diode overlaps the island portion.

In an embodiment, the display panel may further include an inorganic insulating layer which is arranged between the substrate and the light-emitting diode and overlaps the island portion, wherein a groove defined in the inorganic insulating layer overlaps the first opening or the second opening.

In an embodiment, the inorganic insulating layer may have a shape which includes a plurality of islands, and the plurality of islands may be spaced apart from each other by the groove.

In an embodiment, recesses defined in the inorganic insulating layer may be adjacent to opposite ends of the first opening and opposite ends of the second opening.

In an embodiment, the first opening may include an extension portion at one or more of a first end of the first opening and a second end of the first opening, wherein the second end is opposite the first end in the first direction, and a width of the extension portion is greater than the first width.

In an embodiment, a width of an end of the first opening in the first direction may be less than a width of a central portion of the first opening.

In an embodiment, the first opening may have a shape in which a central portion of the first opening in the first direction is recessed in the second direction.

According to one or more embodiments, a display panel includes a substrate having a plurality of first openings which are defined in the substrate and extend in a first direction and a plurality of second openings which are defined in the substrate and extend in a second direction crossing the first direction, the substrate including a plurality of island portions which are each partially surrounded by one or more first openings of the plurality of first openings and one or more second openings of, and an inorganic insulating layer which is disposed on the substrate, wherein a groove defined in the inorganic insulating layer overlaps the plurality of first openings and the plurality of second openings, wherein the inorganic insulating layer has a shape which includes a plurality of islands, and the plurality of islands are spaced apart from each other by the groove and overlap the plurality of island portions of the substrate.

In an embodiment, the display panel may further include a plurality of light-emitting diodes which overlap each of the plurality of islands and are disposed on the substrate.

In an embodiment, at least one of a first width of a first opening of the plurality of first openings in the second direction or a second width of a second opening of the plurality of second openings in the first direction may range from about 6 micrometers to about 8 micrometers.

In an embodiment, the substrate may further include a bridge portion between a first opening among the plurality of first openings and a second opening among the plurality of second openings.

In an embodiment, the bridge portion may include a first bridge portion which extends in the first direction and a second bridge portion which extends in the second direction, and at least one of a length of the first bridge portion in the first direction or a length of the second bridge portion in the second direction ranges from about 17 micrometers to about 25 micrometers.

In an embodiment, at least some of the plurality of island portions of the substrate may be connected to each other by the bridge portion.

In an embodiment, recesses defined in the inorganic insulating layer are adjacent to opposite ends of each of a first opening among the plurality of first openings and a second opening among the plurality of second openings.

In an embodiment, a second-direction width of a portion of a first opening among the plurality of first openings and a second-direction width of another portion of the first opening may be different from one another.

In an embodiment, a width of a first opening included among the plurality of first openings with reference to the second direction may change along the first direction.

In an embodiment, the substrate may include an extension portion at opposite ends of the first opening, and a width of the extension portion may be greater than a width of the first opening in the second direction.

According to one or more embodiments, an electronic device may include a display panel according to one or more embodiments described herein.

According to one or more embodiments, an electronic device may include a display unit, a display panel corresponding to the display unit according to one or more embodiments described herein, and a stroke which is disposed under the display panel and moves up and down.

In an embodiment, the electronic device may further include a frame in which the display panel and the stroke are accommodated.

In an embodiment, the electronic device may include a wearable electronic device.

In an embodiment, the display panel may be stretchable in three dimensions by the stroke.

In an embodiment, the display unit may have a dome shape in a state in which the display panel is not stretched in the three dimensions.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display panel according to an embodiment;

FIG. 2A is a perspective view of the display panel stretched in a first direction;

FIG. 2B is a perspective view of the display panel stretched in the first direction;

FIG. 2C is a perspective view of the display panel stretched in a second direction;

FIG. 2D is a perspective view of the display panel stretched in the first direction and the second direction;

FIG. 2E is a perspective view of the display panel stretched in a third direction;

FIG. 3 is a plan view of the display panel according to an embodiment;

FIG. 4 is a cross-sectional view of the display panel according to an embodiment;

FIG. 5 is a plan view of a substrate of the display panel according to an embodiment;

FIG. 6 is a plan view of an inorganic insulating layer of the display panel according to an embodiment;

FIG. 7A is a plan view of the substrate of the display panel according to an embodiment;

FIG. 7B is a plan view of the substrate of the display panel according to an embodiment;

FIG. 7C is a plan view of the substrate of the display panel according to an embodiment;

FIG. 7D is a plan view of the substrate of the display panel according to an embodiment;

FIG. 8A is an equivalent circuit diagram of a pixel of the display panel according to an embodiment;

FIG. 8B is an equivalent circuit diagram of the pixel of the display panel according to an embodiment;

FIG. 8C is an equivalent circuit diagram of the pixel of the display panel according to an embodiment;

FIG. 9A is a cross-sectional view of a light-emitting diode of the display panel according to an embodiment;

FIG. 9B is a cross-sectional view of the light-emitting diode of the display panel according to an embodiment;

FIG. 9C is a cross-sectional view of the light-emitting diode of the display panel according to an embodiment;

FIG. 9D is a cross-sectional view of the light-emitting diode of the display panel according to an embodiment;

FIG. 9E is a cross-sectional view of the light-emitting diode of the display panel according to an embodiment;

FIG. 10 is a schematic perspective view of an electronic device including the display panel, according to an embodiment;

FIG. 11 is a block diagram illustrating an electronic device including a display panel, according to an embodiment;

FIG. 12A is a perspective view of the electronic device according to an embodiment;

FIG. 12B is a perspective view of the electronic device according to an embodiment;

FIG. 13 is a perspective view of an electronic device according to an embodiment; and

FIG. 14 is a perspective view of the electronic device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are described herein, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, certain embodiments will be illustrated in the drawings and described in detail in the written description. Hereinafter, effects and features of the disclosure and a method for accomplishing them will be described more fully with reference to the accompanying drawings, in which embodiments of the disclosure are illustrated. This disclosure may, however, be embodied in many different forms and should not be construed as limited to the embodiments set forth herein.

One or more embodiments will be described herein in more detail with reference to the accompanying drawings. Those components that are the same or are in correspondence are rendered the same reference numeral regardless of the figure number, and redundant descriptions thereof are omitted.

In an embodiment below, terms such as, for example, “first” and “second,” are used herein to describe a variety of elements, but the elements are not limited by the terms. Such terms are used for the purpose of distinguishing one element from another element.

In an embodiment below, an expression used in the singular encompasses the expression of the plural, unless it has a clearly different meaning in the context.

In an embodiment below, terms, such as, for example, “include” or “comprise,” may be construed to denote a certain characteristic or element, or a combination thereof, but may not be construed to exclude the existence of or a possibility of addition of one or more other characteristics, elements, or combinations thereof.

It will be understood that when a layer, region, or component is referred to as being “formed on” another layer, region, or component, it can be directly or indirectly formed on the other layer, region, or component. That is, for example, intervening layers, regions, or components may be present.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ±30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel”means approximately or actually parallel.

Sizes of elements in the drawings may be exaggerated or reduced for convenience of explanation. In other words, because sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

It will be understood that when a layer, region, or component is referred to as being “connected” to another layer, region, or component, it may be “directly connected” to the other layer, region, or component or may be “indirectly connected” to the other layer, region, or component with other layer, region, or component therebetween. For example, it will be understood that when a layer, region, or component is referred to as being “electrically connected” to another layer, region, or component, it may be “directly electrically connected” to the other layer, region, or component or may be “indirectly electrically connected” to other layer, region, or component with other layer, region, or component therebetween.

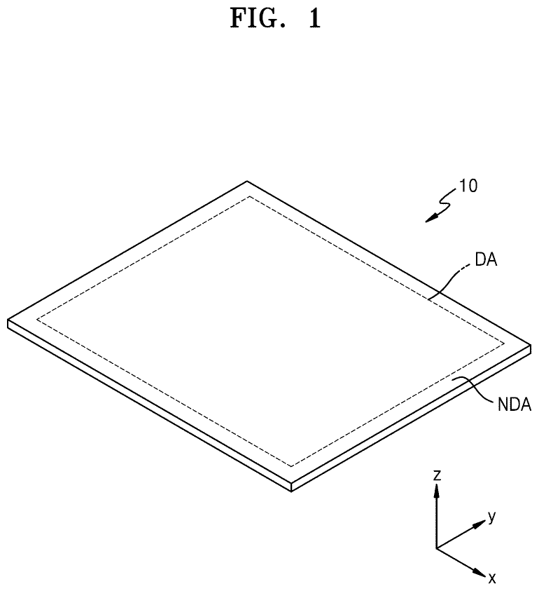

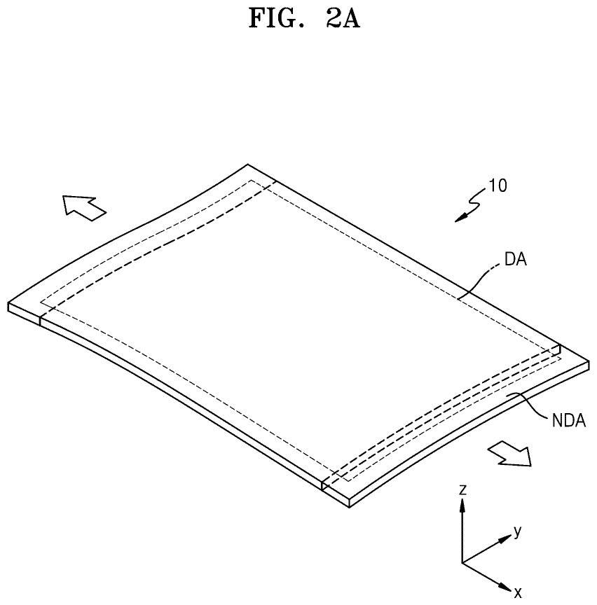

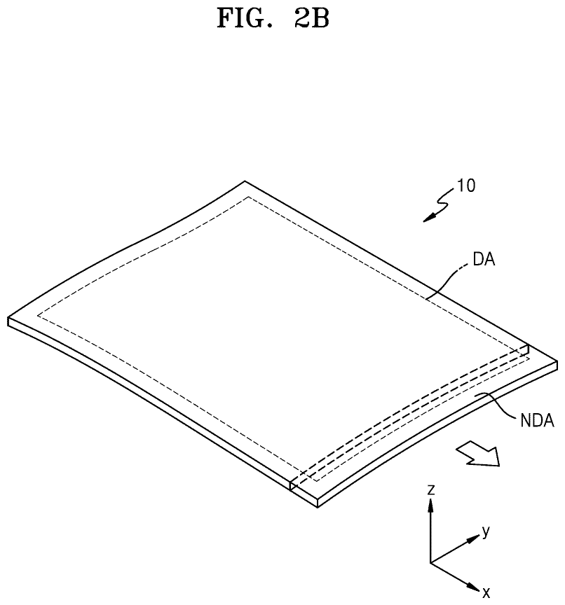

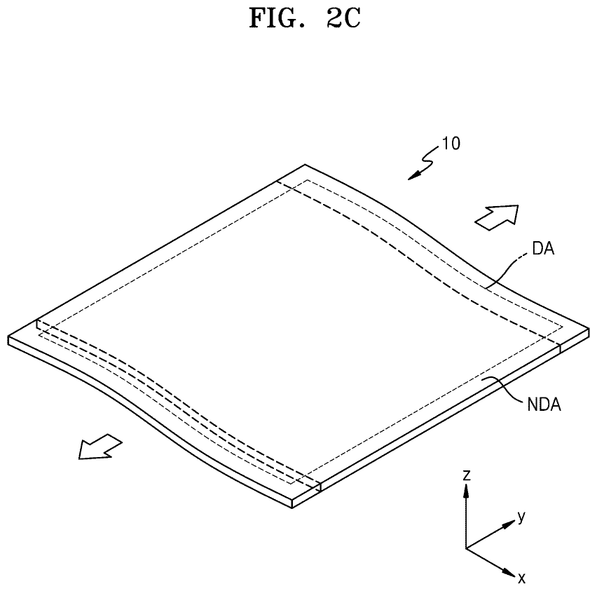

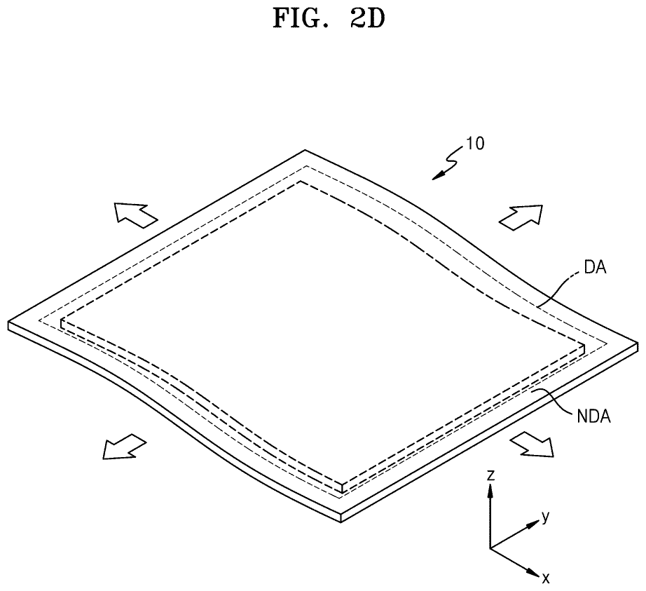

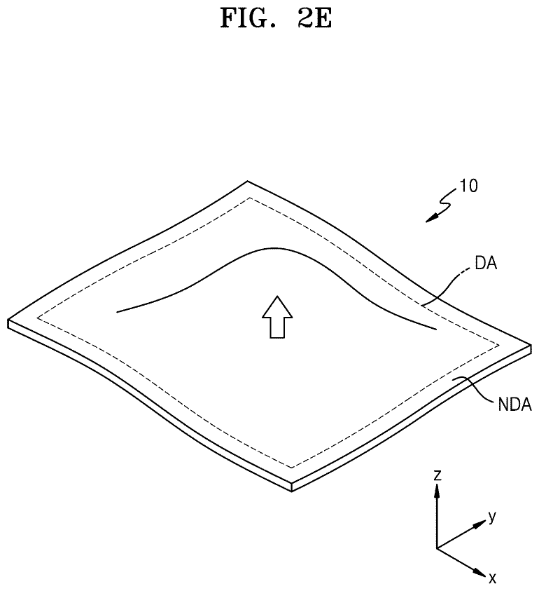

FIG. 1 is a perspective view schematically illustrating a display panel 10 according to an embodiment. FIGS. 2A and 2B are perspective views of the display panel 10 of FIG. 1, the display panel 10 being stretched in a first direction. FIG. 2C is a perspective view of the display panel 10 of FIG. 1, the display panel 10 being stretched in a second direction. FIG. 2D is a perspective view of the display panel 10 of FIG. 1, the display panel 10 being stretched in the first direction and the second direction. FIG. 2E is a perspective view of the display panel 10 of FIG. 1, the display panel 10 being stretched in a third direction.

Referring to FIG. 1, the display panel 10 may include a display area DA and a non-display area NDA. The display area DA may include a plurality of pixels. The display panel 10 may provide a certain image by using light emitted from the plurality of pixels. The non-display area NDA may be arranged outside the display area DA. The non-display area NDA may surround the display area DA entirely.

The display panel 10 may extend or contract in various directions. The display panel 10 may extend in the first direction (e.g., an x direction and/or a −x direction) by an external force applied by an external object or user. In an embodiment, as illustrated in FIGS. 2A and 2B, the display area DA and/or the non-display area NDA of the display panel 10 may extend in the first direction (e.g., the x direction and/or the −x direction). For example, as illustrated in FIG. 2A, the display panel 10 may extend in the x direction and the −x direction. In another example, as illustrated in FIG. 2B, one side of the display panel 10 may be fixed and may extend in the x direction.

The display panel 10 may extend in the second direction (e.g., a y direction and/or a −y direction) by an external force applied an external object or user. In an embodiment, as illustrated in FIG. 2C, the display area DA and/or the non-display area NDA of the display panel 10 may extend in the y direction and the −y direction. In another embodiment, one side of the display panel 10 may be fixed and may extend in the y direction or the −y direction.

By an external force applied from an external object or a person's body part, the display panel 10 may extend in a plurality of directions, e.g., the first direction (e.g., the x direction and/or the −x direction) and the second direction (e.g., the y direction and/or the −y direction). As illustrated in FIG. 2D, the display area DA and/or the non-display area NDA of the display panel 10 may extend in a ±x direction and a ±y direction.

The display panel 10 may extend in the third direction (e.g., a z direction or a −z direction) by an external force applied by an external object or a person's body part. In an embodiment, FIG. 2E illustrates a portion of the display panel 10, e.g., a partial area of the display area DA, protruding in the z direction. In another embodiment, a portion of the display panel 10, e.g., a partial area of the display area DA, may protrude in the z direction (or may be recessed in the −z direction).

In FIGS. 2A to 2E, the display panel 10 extends in the first direction, the second direction, and/or the third direction. However, one or more embodiments are not limited thereto. In another embodiment, the display panel 10 may be variously deformed to an irregular shape, such as, for example, being bent or twisted along two or more axes.

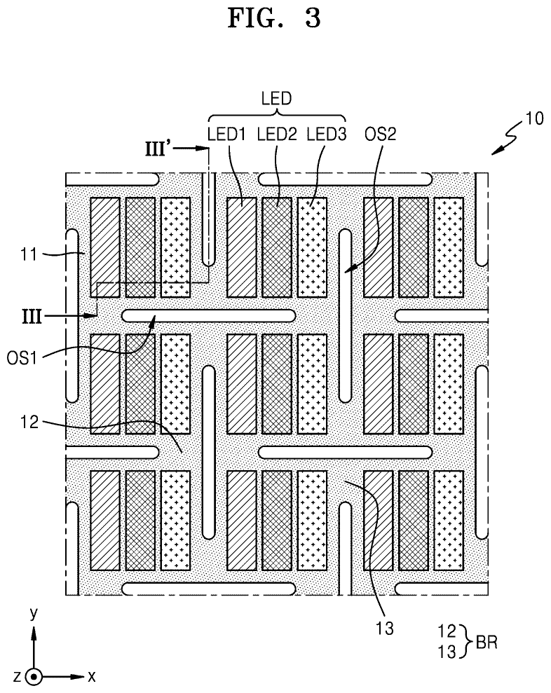

FIG. 3 is a schematic plan view of a portion of the display panel 10 according to an embodiment.

Referring to FIG. 3, the display panel 10 may include an island portion 11, a bridge portion BR, a first opening OS1, and a second opening OS2. In an embodiment, it may be understood that an area in which the island portion 11 is arranged is a first area, and an area in which the bridge portion BR, the first opening OS1, and the second opening OS2 are arranged is a second area.

The first area and the second area of the display panel 10 may have different elongations. For example, the display panel 10 may include the first area with a relatively small elongation and the second area with a relatively large elongation. The elongation as used herein indicates a numerical value representing a change (ΔL/L) in a length by which the display panel 10 may extend without physical damage to the display panel 10 when an external force is applied to the display panel 10. Here, ΔL indicates a change in length of the display panel 10, and L indicates an initial length of the display panel 10. Therefore, elongations of the first area and the second area may respectively represent changes in lengths of the first area and the second area when the same external force is applied to the first area and the second area.

Cases in which the elongation of the first area is less than the elongation of the second area may indicate that deformation of the first area occurs relatively less due to the external force. Thus, the first area may also be referred to as a low-strain area, and the second area may also be referred to as a high-strain area.

The display panel 10 may include a plurality of island portions 11. The island portions 11 may be spaced apart from each other and may be arranged in a two-dimensional manner. The island portions 11 may be repeatedly arranged in the first direction (e.g., the ±x direction) and the second direction (e.g., the ±y direction). The island portions 11 may be an area in which pixels are arranged. Therefore, an area (e.g., the first area) in which the island portion 11 is located may be referred to as a pixel area or an emission area. One or more pixels may be arranged in each island portion 11. A light-emitting diode LED corresponding to each of the pixels may be arranged in the island portion 11. In FIG. 3, three light-emitting diodes LED, e.g., a first light-emitting diode LED1, a second light-emitting diode LED2, and a third light-emitting diode LED3, are arranged in the island portion 11. However, the number of light-emitting diodes LED arranged in the island portion 11 may be variously modified. The first, second, and third light-emitting diodes LED1, LED2, and LED3 may respectively emit light of different colors, e.g., red light, green light, and blue light.

A pixel circuit for operation of the light-emitting diode LED may be arranged in the island portion 11. The pixel circuit may include a transistor and a capacitor.

The second area may be located between adjacent island portions 11 (or first areas). The second area may have a shape surrounding each island portion 11. The first opening OS1, the second opening OS2, and the bridge portion BR may be arranged in the second area.

The first opening OS1 may extend in the first direction (e.g., the ±x direction). The first opening OS1 may be arranged between the island portions 11 which are arranged in the second direction (e.g., the ±y direction). The first opening OS1 may be defined across the entire display panel 10 in the third direction, e.g., a thickness direction (e.g., the ±z direction) of the display panel 10. In other words, the first opening OS1 may be a through hole.

The second opening OS2 may extend in the second direction (e.g., the ±y direction). The second opening OS2 may be arranged between the island portions 11 which are arranged in the first direction (e.g., the ±x direction). The second opening OS2 may be defined across the entire display panel 10 in the third direction, e.g., the thickness direction (e.g., the ±z direction) of the display panel 10. In other words, the second opening OS2 may be a through hole.

When viewed based on one island portion 11, two first openings OS1 and two second openings OS2 may be arranged around the island portion 11 in a propeller shape that rotates clockwise (or counterclockwise).

The bridge portion BR may include a first bridge portion 12 and a second bridge portion 13. As described herein, some layers among layers included in the display panel 10 (e.g., not all of the layers) may be arranged in the bridge portion BR.

The first bridge portion 12 may be a part of the display panel 10. The first bridge portion 12 may extend in the first direction (e.g., the ±x direction), between the first opening OS1 and the second opening OS2 which are adjacent to each other. The first bridge portion 12 may connect, in the second direction (e.g., the ±y direction), two island portions 11 arranged in the second direction (e.g., the ±y direction). For example, the first bridge portion 12 may be arranged between the first opening OS1 and the second opening OS2 and may be understood as a portion of the display panel 10 that connects two island portions 11 in the second direction (e.g., the ±y direction). The display panel 10 may include a plurality of first bridge portions 12.

The second bridge portion 13 may be a part of the display panel 10. The second bridge portion 13 may extend in the second direction (e.g., the ±y direction), between the first opening OS1 and the second opening OS2 which are adjacent to each other. The second bridge portion 13 may connect, in the first direction (e.g., the ±x direction), two island portions 11 arranged in the first direction (e.g., the ±x direction). For example, the second bridge portion 13 may be arranged between the first opening OS1 and the second opening OS2 and may be understood as a portion of the display panel 10 that connects two island portions 11 in the first direction (e.g., the ±x direction). The display panel 10 may include a plurality of second bridge portions 13.

The first bridge portion 12, the second bridge portion 13, the first opening OS1, and the second opening OS2 may surround the island portions 11 together.

Lines (e.g., a gate line, a data line, a first voltage line, a second voltage line, or the like) electrically connected to respective pixel circuits arranged in respective two adjacent island portions 11 may pass through the bridge portion BR, e.g., the first bridge portion 12 and the second bridge portion 13.

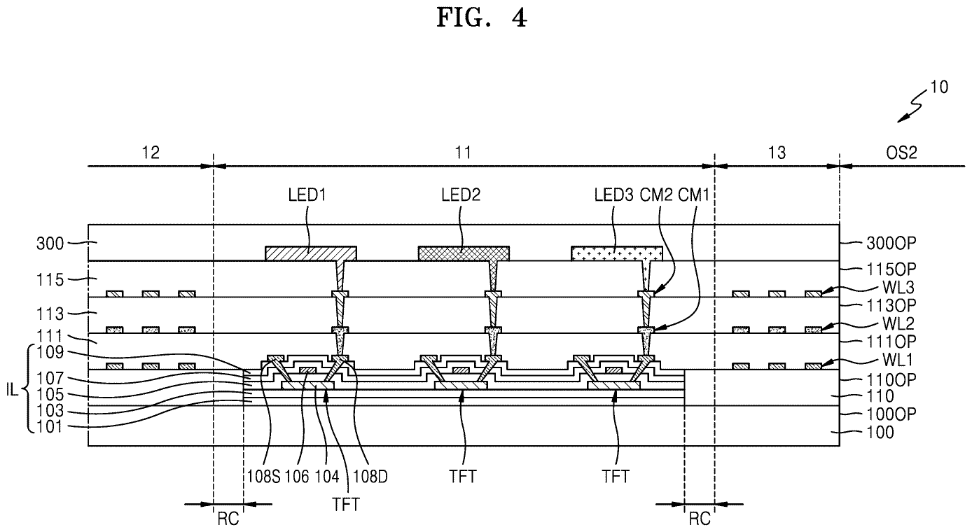

FIG. 4 is a cross-sectional view of the display panel 10 according to an embodiment, and is a cross-sectional view of the display panel 10, taken along line III-III′ of FIG. 3.

Referring to FIG. 4, the display panel 10 may include a substrate 100, first, second, and third light-emitting diodes LED1, LED2, and LED3 disposed on the substrate 100, and thin-film transistors TFT respectively connected to the first, second, and third light-emitting diodes LED1, LED2, and LED3.

The substrate 100 may be a flexible substrate. The substrate 100 may include a polymer. For example, the substrate 100 may include polyimide (PI). However, one or more embodiments are not necessarily limited thereto, and the substrate 100 may have a multi-layer structure that includes a layer including a polymer and a layer including an inorganic insulating material. In this case, for example, the polymer may be PI, and the inorganic insulating material may be at least one selected from among silicon oxide (SiO₂), silicon nitride (SiNₓ), and silicon oxynitride (SiON).

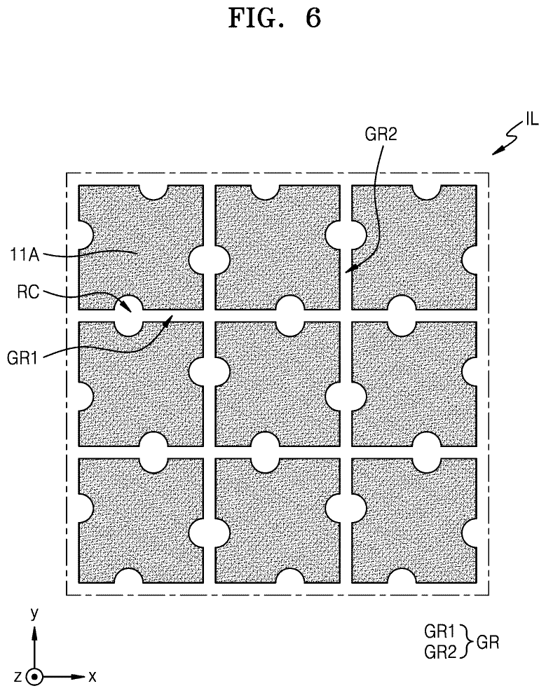

An inorganic insulating layer IL may be disposed on the substrate 100. The inorganic insulating layer IL may be arranged in the island portion 11, without being arranged in other portions of the substrate 100. In other words, the inorganic insulating layer IL may not be arranged in the first bridge portion 12 or the second bridge portion 13. The arrangement of the inorganic insulating layer IL may contribute to a difference in elongation between the first area and the second area. In an area adjacent to the first bridge portion 12 or the second bridge portion 13, the inorganic insulating layer IL may include a recess RC which is defined in the island portion 11. The recess RC is described herein with reference to FIG. 6.

The inorganic insulating layer IL may include a first inorganic insulating layer 101, a second inorganic insulating layer 103 which is on the first inorganic insulating layer 101, a third inorganic insulating layer 105 which is on the second inorganic insulating layer 103, a fourth inorganic insulating layer 107 which is on the third inorganic insulating layer 105, and a fifth inorganic insulating layer 109 which is on the fourth inorganic insulating layer 107.

The first inorganic insulating layer 101 may be disposed on the substrate 100. The first inorganic insulating layer 101 may include an inorganic insulating material, such as, for example, SiO2, SiNx, SiON, aluminum oxide (Al₂O₃), titanium oxide (TiO₂), tantalum oxide (Ta₂O₅), hafnium oxide (HfO₂), or zinc oxide (ZnO₂). The first inorganic insulating layer 101 may have a single-or multi-layer structure. In an embodiment, the first inorganic insulating layer 101 may be a barrier layer.

The second inorganic insulating layer 103 may be disposed on the first inorganic insulating layer 101. The second inorganic insulating layer 103 may include an inorganic insulating material, such as, for example, SiO₂, SiNₓ, SiON, Al₂O₃, TiO₂, Ta₂O₅, HfO₂, or ZnO₂. The second inorganic insulating layer 103 may have a single-or multi-layer structure. In an embodiment, the second inorganic insulating layer 103 may be a buffer layer.

The thin-film transistors TFT may be disposed on the second inorganic insulating layer 103. The thin-film transistor TFT may include an active layer 104, a gate electrode 106, a source electrode 108S, and a drain electrode 108D. The active layer 104 may be disposed on the second inorganic insulating layer 103 and may be patterned to correspond to each of the thin-film transistors TFT. The active layer 104 may include a drain region which overlaps the drain electrode 108D, a source region which overlaps the source electrode 108S, and a channel region which is between the drain region and the source region. The source region and the drain region of the active layer 104 may be doped with impurities.

The third inorganic insulating layer 105 may be disposed on the active layer 104. The third inorganic insulating layer 105 may include an inorganic insulating material, such as, for example, SiO₂, SiNₓ, SiON, Al₂O₃, TiO₂, Ta₂O₅, HfO₂, or ZnO₂. The third inorganic insulating layer 105 may have a single-or multi-layer structure. In an embodiment, the third inorganic insulating layer 105 may be a first gate insulating layer. FIG. 4 illustrates a case where the third inorganic insulating layer 105 covers the active layer 104 entirely. In another embodiment, the third inorganic insulating layer 105 may be patterned to correspond to the active layer 104 (or the channel region of the active layer 104).

The gate electrode 106 may be disposed on the third inorganic insulating layer 105. The gate electrode 106 may overlap the channel region of the active layer 104. In other words, the gate electrode 106 may be patterned to overlap the channel region of the active layer 104. The gate electrode 106 may include at least one of materials, including aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and copper (Cu), and may have a single-or multi-layer structure including the materials described herein.

The fourth inorganic insulating layer 107 may be disposed on the gate electrode 106. The fourth inorganic insulating layer 107 may include an inorganic insulating material, such as, for example, SiO₂, SiNₓ, SiON, Al₂O₃, TiO₂, Ta₂O₅, HfO₂, or ZnO₂. The third inorganic insulating layer 105 may have a single-or multi-layer structure. In an embodiment, the fourth inorganic insulating layer 107 may be a second gate insulating layer.

The fifth inorganic insulating layer 109 may be disposed on the fourth inorganic insulating layer 107. The fifth inorganic insulating layer 109 may include an inorganic insulating material, such as, for example, SiO₂, SiNₓ, SiON, Al₂O₃, TiO₂, Ta₂O₅, HfO₂, or ZnO₂. The fifth inorganic insulating layer 109 may have a single- or multi-layer structure. In an embodiment, the fifth inorganic insulating layer 109 may be an interlayer insulating layer.

Contact holes overlapping the source region or the drain region of the active layer 104 may be defined in the third inorganic insulating layer 105, the fourth inorganic insulating layer 107, and the fifth inorganic insulating layer 109. The source electrode 108S and the drain electrode 108D may be disposed on the fifth inorganic insulating layer 109. The source electrode 108S may overlap the source region of the active layer 104, and the drain electrode 108D may overlap the drain electrode 108D of the active layer 104. The source electrode 108S and the drain electrode 108D may each be connected (e.g., electrically connected) to the active layer 104 through the contact holes defined in the third inorganic insulating layer 105, the fourth inorganic insulating layer 107, and the fifth inorganic insulating layer 109.

In the first bridge portion 12, the second bridge portion 13, and the recess RC, an auxiliary layer 110 may be disposed on the substrate 100. The auxiliary layer 110 may provide a flat surface on which first lines WL1 may be disposed. In an embodiment, an upper surface of the auxiliary layer 110 and an upper surface of the fifth inorganic insulating layer 109 may be arranged in a same layer.

The first lines WL1 may be disposed on the auxiliary layer 110. The first lines WL1 may include lines which are connected to a pixel circuit, such as, for example, a gate line, a data line, a first voltage line, a second voltage line. The first lines WL1, the source electrode 108S, and the drain electrode 108D may be arranged in a same layer. In an embodiment, the first lines WL1, the source electrodes 108S, and the drain electrodes 108D may be formed in a same process. FIG. 4 illustrates an example embodiment in which three first lines WL1 are arranged in each of the first bridge portion 12 and the second bridge portion 13. In an embodiment, the auxiliary layer 110 may be omitted, and the first lines WL1 may be disposed on an upper surface of the substrate 100.

A first organic insulating layer 111 may be arranged such that the first organic insulating layer 111 covers the source electrode 108S, the drain electrode 108D, and the first lines WL1. The first organic insulating layer 111 may be a planarization layer with an approximately flat upper surface. For example, the first organic insulating layer 111 may include an organic insulating material, such as, for example, acryl, benzocyclobutene (BCB), or hexamethyldisiloxane (HMDSO).

A first contact metal CM1 may be disposed on the first organic insulating layer 111. The first contact metal CM1 may be arranged in the island portion 11. The first contact metal CM1 may be connected to the drain electrode 108D through a contact hole defined in the first organic insulating layer 111. Second lines WL2 may be disposed on the first organic insulating layer 111. The second lines WL2 may be arranged in the first bridge portion 12 or the second bridge portion 13. The first contact metal CM1 and the second lines WL2 may be arranged in a same layer. In an embodiment, the first contact metal CM1 and the second lines WL2 may be formed in a same process. FIG. 4 illustrates an example embodiment in which three second lines WL2 are arranged in each of the first bridge portion 12 and the second bridge portion 13.

A second organic insulating layer 113 may be arranged such that the second organic insulating layer 113 covers the first contact metal CM1 and the second lines WL2. The second organic insulating layer 113 may be a planarization layer with an approximately flat upper surface. For example, the second organic insulating layer 113 may include an organic insulating material, such as, for example, acryl, BCB, or HMDSO.

A second contact metal CM2 may be disposed on the second organic insulating layer 113. The second contact metal CM2 may be arranged in the island portion 11. The second contact metal CM2 may be connected to the first contact metal CM1 through a contact hole defined in the second organic insulating layer 113. Third lines WL3 may be disposed on the second organic insulating layer 113. The third lines WL3 may be arranged in the first bridge portion 12 or the second bridge portion 13. The second contact metal CM2 and the third lines WL3 may be arranged in a same layer. In an embodiment, the second contact metal CM2 and the third lines WL3 may be formed in a same process. FIG. 4 illustrates an example embodiment in which three third lines WL3 are arranged in each of the first bridge portion 12 and the second bridge portion 13.

A third organic insulating layer 115 may be arranged such that the third organic insulating layer 115 covers the second contact metal CM2 and the third lines WL3. The third organic insulating layer 115 may be a planarization layer with an approximately flat upper surface. For example, the third organic insulating layer 115 may include an organic insulating material, such as, for example, acryl, BCB, or HMDSO.

The first light-emitting diode LED1, the second light-emitting diode LED2, and the third light-emitting diode LED3 may be disposed on the third organic insulating layer 115. The first light-emitting diode LED1, the second light-emitting diode LED2, and the third light-emitting diode LED3 may be arranged in the island portion 11. The first light-emitting diode LED1, the second light-emitting diode LED2, and the third light-emitting diode LED3 may be connected (e.g., electrically connected) to a corresponding thin-film transistor TFT through the first contact metal CM1 and the second contact metal CM2.

An encapsulation layer 300 may be arranged such that the encapsulation layer 300 covers the first light-emitting diode LED1, the second light-emitting diode LED2, and the third light-emitting diode LED3. The encapsulation layer 300 may include at least one of an inorganic encapsulation layer which includes an inorganic insulating material and an organic encapsulation layer which includes an organic insulating material. In an embodiment, the encapsulation layer 300 may include a first inorganic encapsulation layer, a second inorganic encapsulation layer which is on the first inorganic encapsulation layer, and an organic encapsulation layer which is between the first inorganic encapsulation layer and the second inorganic encapsulation layer.

The second opening OS2 may be defined across the entire display panel 10 in the third direction, e.g., the thickness direction of the display panel 10 (e.g., the ±z direction). For example, the second opening OS2 may be a through hole. In an embodiment, the second opening OS2 may include an opening 100OP defined in the substrate 100, an opening 110OP defined in the auxiliary layer 110, an opening 111OP defined in the first organic insulating layer 111, an opening 113OP defined in the second organic insulating layer 113, an opening 115OP defined in the third organic insulating layer 115, and an opening 300OP defined in the encapsulation layer 300 altogether. In other words, the openings 100OP, 110OP, 111OP, 113OP, 115OP, and 300OP respectively defined in the substrate 100, the auxiliary layer 110, the first organic insulating layer 111, the second organic insulating layer 113, the third organic insulating layer 115, and the encapsulation layer 300 may be spatially connected and may together constitute the second opening OS2.

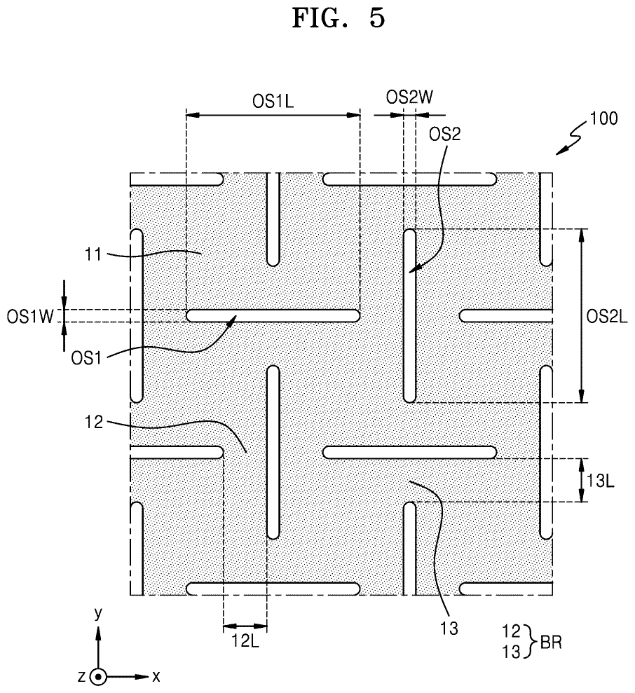

FIG. 5 is a schematic plan view of a portion of the substrate 100 of the display panel 10 according to an embodiment.

The first opening OS1, the second opening OS2, the first bridge portion 12, and the second bridge portion 13 of the display panel 10, described herein with reference to FIG. 3, may also be similarly applicable to the substrate 100 of the display panel 10. For example, the second opening OS2 may also be defined in the substrate 100 and may correspond to the opening 100OP defined in the substrate 100 of FIG. 4. For convenience of description, the first opening OS1, the second opening OS2, the first bridge portion 12, and the second bridge portion 13 which are defined in the substrate 100 are mainly described herein. However, features described herein are not limited to the substrate 100 only, and may be extended and applied to the entire display panel 10.

Referring to FIG. 5, the substrate 100 may include the first opening OS1, the second opening OS2, and the bridge portion BR. The bridge portion BR may include the first bridge portion 12 and the second bridge portion 13.

A length of the first opening OS1 in the first direction (e.g., the ±x direction) is defined as a first length OS1L. A length of the second opening OS2 in the second direction (e.g., the ±y direction) is defined as a second length OS2L. A length of the first bridge portion 12 in the first direction (e.g., the ±x direction) is defined as a third length 12L. A length of the second bridge portion 13 in the second direction (e.g., the ±y direction) is defined as a fourth length 13L. A length (or width) of the first opening OS1 in the second direction (e.g., the ±y direction) is defined as a first width OS1W. A length (or width) of the second opening OS2 in the first direction (e.g., the ±x direction) is defined as a second width OS2W.

In an embodiment, the first length OS1L may range from about 115 micrometers (μm) to about 125 μm. In an embodiment, the first length OS1L may range from about 117 μm to about 123 μm. In an embodiment, the first length OS1L may be about 120 μm.

In an embodiment, the second length OS2L may range from about 115 μm to about 125 μm. In an embodiment, the second length OS2L may range from about 117 μm to about 123 μm. In an embodiment, the second length OS2L may be about 120 μm.

In an embodiment, the first length OS1L may be equal to the second length OS2L.

In an embodiment, the third length 12L may range from about 17 μm to about 25 μm. In an embodiment, the third length 12L may range from about 19 μm to about 23 μm. In an embodiment, the third length 12L may be about 21 μm.

In an embodiment, the fourth length 13L may range from about 17 μm to about 25 μm. In an embodiment, the fourth length 13L may range from about 19 μm to about 23 μm. In an embodiment, the fourth length 13L may be about 21 μm.

In an embodiment, the third length 12L may be equal to the fourth length 13L.

In an embodiment, the first width OS1W may range from about 6 μm to about 8 μm. In an embodiment, the first width OS1W may range from about 6.5 μm to about 7.5 μm. In an embodiment, the first width OS1W may be about 7 μm.

In an embodiment, the second width OS2W may range from about 6 μm to about 8 μm. In an embodiment, the second width OS2W may range from about 6.5 μm to about 7.5 μm. In an embodiment, the second width OS2W may be about 7 μm.

In an embodiment, the first width OS1W may be equal to the second width OS2W.

Features other than the features described herein of the first opening OS1, the second opening OS2, the first bridge portion 12, and the second bridge portion 13 are same as those described with reference to FIG. 3.

FIG. 6 is a plan view schematically illustrating a portion of the inorganic insulating layer IL of the display panel 10 according to an embodiment.

Features of the inorganic insulating layer IL described herein with reference to FIG. 6 may be respectively applicable to the first inorganic insulating layer 101, the second inorganic insulating layer 103, the third inorganic insulating layer 105, the fourth inorganic insulating layer 107, and the fifth inorganic insulating layer 109 described herein with reference to FIG. 4.

Referring to FIGS. 4 to 6 together, a groove GR may be defined in the inorganic insulating layer IL and divide the inorganic insulating layer IL into a plurality of islands 11A. The groove GR defined in the inorganic insulating layer IL may have an overall mesh shape. Therefore, the plurality of islands 11A of the inorganic insulating layer IL may be spaced apart from each other. The island 11A of the inorganic insulating layer IL may overlap the island portion 11 of the substrate 100 described herein.

The groove GR defined in the inorganic insulating layer IL may include a first groove GR1 which extends in the first direction (e.g., the ±x direction). The groove GR defined in the inorganic insulating layer IL may include a second groove GR2 which extends in the second direction (e.g., the ±y direction). The first groove GR1 and the second groove GR2 of the inorganic insulating layer IL may cross and may be spatially connected. Therefore, a mesh-like structure of the groove GR defined in the inorganic insulating layer IL may be implemented.

The first groove GR1 defined in the inorganic insulating layer IL may overlap the first opening OS1 or the second opening OS2. The second groove GR2 defined in the inorganic insulating layer IL may overlap the first opening OS1 or the second opening OS2. Therefore, the display panel 10 may be opened in the entire thickness direction (e.g., the ±z direction), in an area where the first groove GR1 or the second groove GR2 overlaps the first opening OS1 or the second opening OS2.

The first groove GR1 defined in the inorganic insulating layer IL may overlap the first bridge portion 12. The second groove GR2 defined in the inorganic insulating layer IL may overlap the second bridge portion 13. In an embodiment, the auxiliary layer 110 may be arranged in an area where the first groove GR1 overlaps the first bridge portion 12. In an embodiment, the auxiliary layer 110 may be arranged in an area where the second groove GR2 overlaps the second bridge portion 13.

The groove GR defined in the inorganic insulating layer IL may be defined across the entire inorganic insulating layer IL in the third direction, e.g., the thickness direction of the inorganic insulating layer IL (e.g., the ±z direction). Therefore, the plurality of islands 11A of the inorganic insulating layer IL may be spaced apart from each other.

The inorganic insulating layer IL may have defined therein the recess RC which extends from the groove GR toward the island 11A. In other words, a portion of the island 11A of the inorganic insulating layer IL may be indented. In FIG. 6, four recesses RC are provided per island 11A. However, one or more embodiments are not necessarily limited to this number.

Referring to FIGS. 5 and 6 together, the recesses RC defined in the inorganic insulating layer IL may be arranged adjacent to ends of each of the first opening OS1 or the second opening OS2. In other words, in a plan view, the recesses RC may be defined in the inorganic insulating layer IL to be respectively adjacent to opposite ends of each of the first opening OS1 or the second opening OS2. For example, in a plan view, each of the recesses RC defined in the inorganic insulating layer IL may be adjacent to an end included among opposite ends of the first opening OS1 or an end included among opposite ends of the second opening OS2. For example, in a plan view, the recesses RC may be respectively defined in the inorganic insulating layer IL at locations adjacent to the opposite ends of the first opening OS1 in the first direction (e.g., the ±x direction). Similarly, in a plan view, the recesses RC may be defined in the inorganic insulating layer IL at locations adjacent to opposite ends of the second opening OS2 in the second direction (e.g., the ±y direction).

In an embodiment, the recess RC may have an approximately hemispherical shape. In an embodiment, the hemisphere of the recess RC may have a diameter of about 15 μm to about 20 μm. However, one or more embodiments are not limited this shape of the recess RC.

When the display panel 10 is deformed, stress may be concentrated near an end of the first opening OS1 or the second opening OS2. By removing a portion of the inorganic insulating layer IL, e.g., by forming the recess RC, cracks may be prevented from occurring in the inorganic insulating layer IL in the area described herein where the stress is concentrated.

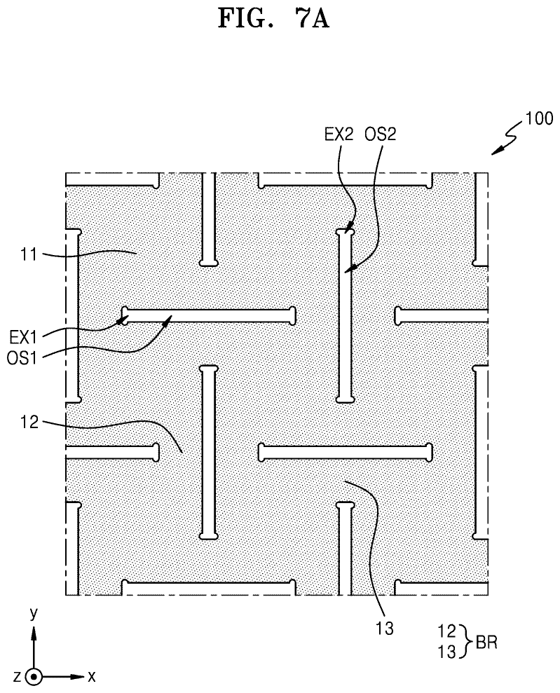

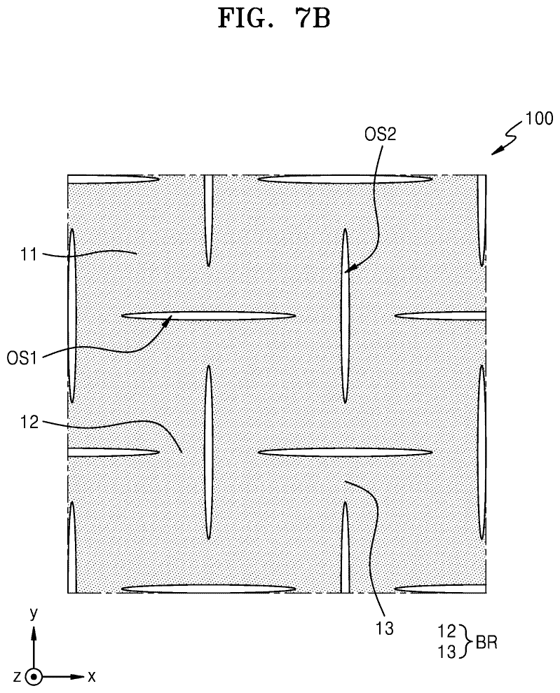

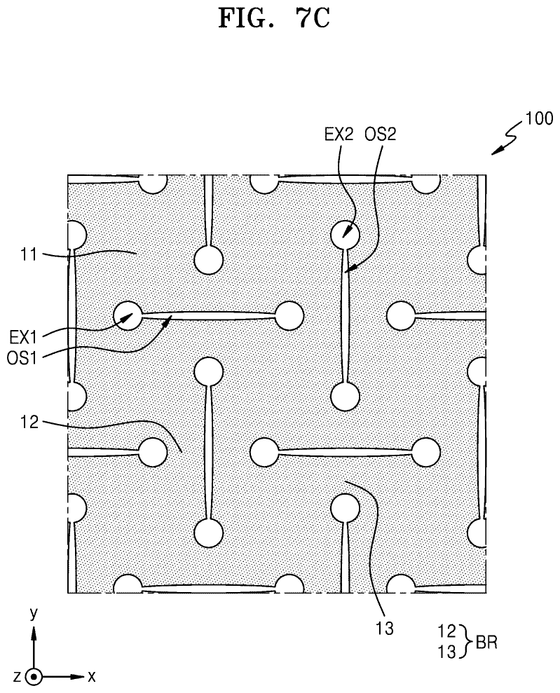

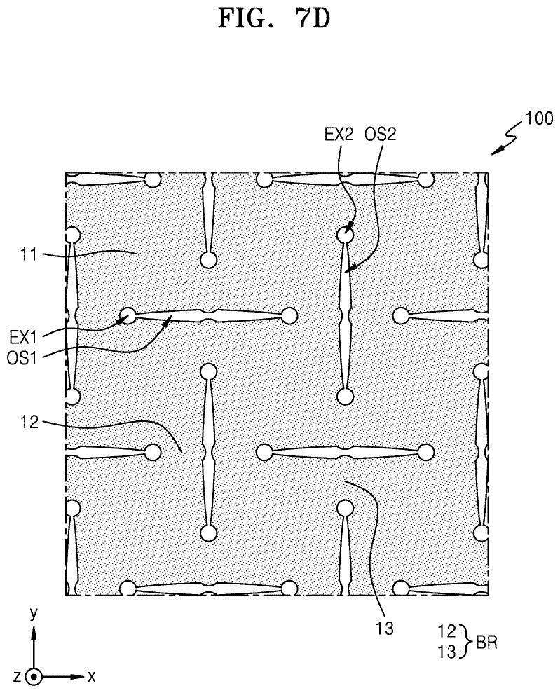

FIGS. 7A, 7B, 7C, and 7D are schematic plan views of the substrate 100 of the display panel 10 according to various embodiments.

FIGS. 7A to 7D show embodiments of various shapes of the first opening OS1 and the second opening OS2 which are defined in the substrate 100. A width of each of the first opening OS1 and the second opening OS2 may vary along a longitudinal direction. In other words, a width of a portion of each of the first opening OS1 and the second opening OS2 may be different from a width of another portion of each of the first opening OS1 and the second opening OS2. For example, in the first opening OS1, a width of the first opening OS1 in the second direction (e.g., the ±y direction) may change along a longitudinal direction of the first opening OS1 (e.g., the first direction or the ±x direction). Similarly, in the second opening OS2, a width of the second opening OS2 in the first direction (e.g., the ±x direction) may change along a longitudinal direction of the second opening OS2 (e.g., the second direction or the ±y direction).

Referring to FIGS. 7A, 7C, and 7D, the first opening OS1 may include a first extension portion EX1 at respective ends of the first opening OS1 in the first direction (e.g., the ±x direction). In an embodiment, a second-direction (e.g., the ±y direction) width of the first extension portion EX1 may be greater than the width of the first opening OS1, e.g., a first width OSW1 (see FIG. 5). In FIG. 7A, the first opening OS1 includes the first extension portion EX1 at both a +x direction end and a −x direction end. However, one or more embodiments are not necessarily limited thereto. The first extension portion EX1 may be provided at one of the +x direction end or the −x direction end of the first opening OS1.

Similarly, the second opening OS2 may include a second extension portion EX2 at each of opposite ends in the second direction (e.g., the ±y direction). In an embodiment, a first-direction (e.g., the ±x direction) width of the second extension portion EX2 may be greater than the width of the second opening OS2, e.g., a second width OSW2 (see FIG. 5). In FIG. 7A, the second opening OS2 includes the second extension portion EX2 at each of a +y direction end and a −y direction end. However, one or more embodiments are not necessarily limited thereto. The second extension portion EX2 may also be provided at one of the +y direction end or the −y direction end of the second opening OS2.

The first extension portion EX1 and the second extension portion EX2 may have various shapes. In an embodiment, the first extension portion EX1 and the second extension portion EX2 may each have an approximately rectangular shape with round corners, as illustrated in FIG. 7A. In an embodiment, the first extension portion EX1 and the second extension portion EX2 may have a circular shape, as illustrated in FIGS. 7C and 7D. In this case, diameters of circles of the first extension portion EX1 and the second extension portion EX2 may be greater than widths of the first opening OS1 and the second opening OS2, respectively.

Referring to FIG. 7B, the widths of the first opening OS1 and the second opening OS2 may each gradually change along one direction.

In an embodiment, in the first opening OS1, a second-direction (e.g., the ±y direction) width of the first opening OS1 may gradually change along the longitudinal direction (e.g., the first direction or the ±x direction) of the first opening OS1. For example, a second-direction (e.g., the ±y direction) width of the first opening OS1 may gradually decrease from a central portion of the first opening OS1 toward an end of the first opening OS1. In other words, the width of an end of the first opening OS1 may be less than a width of the central portion of the first opening OS1.

In an embodiment, in the second opening OS2, a first-direction (e.g., the ±x direction) width of the second opening OS2 may gradually change along the longitudinal direction (e.g., the second direction or the ±y direction) of the second opening OS2. For example, the first-direction (e.g., the ±x direction) width of the second opening OS2 may gradually decrease from the central portion of the second opening OS2 toward an end of the second opening OS2. In other words, the width of the end of the second opening OS2 may be less than the width of the central portion of the second opening OS2.

Referring to FIG. 7C, an embodiment can be seen in which the first opening OS1 and the second opening OS2 which have a decreasing width, illustrated in FIG. 7B, are combined with the first extension portion EX1 and the second extension portion EX2 which have a circular shape.

Referring to FIG. 7D, the first opening OS1 and the second opening OS2 which have a decreasing width, illustrated in FIG. 7B, may be combined with the first extension portion EX1 and the second extension portion EX2 which have a circular shape, and additionally, a portion of the first opening OS1 and the second opening OS2 may be recessed. For example, a central portion of each of the first opening OS1 and the second opening OS2 may be recessed. In an embodiment, in the first opening OS1, the central portion of the first opening OS1 may be recessed in the second direction (e.g., the ±y direction). In an embodiment, in the second opening OS2, the central portion of the second opening OS2 may be recessed in the first direction (e.g., the ±x direction).

The features of the first opening OS1 and the second opening OS2 of the substrate 100 described with reference to FIGS. 7A to 7D may be combined in various ways.

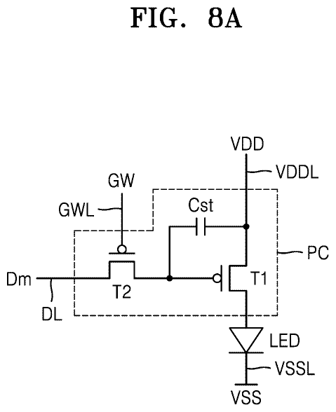

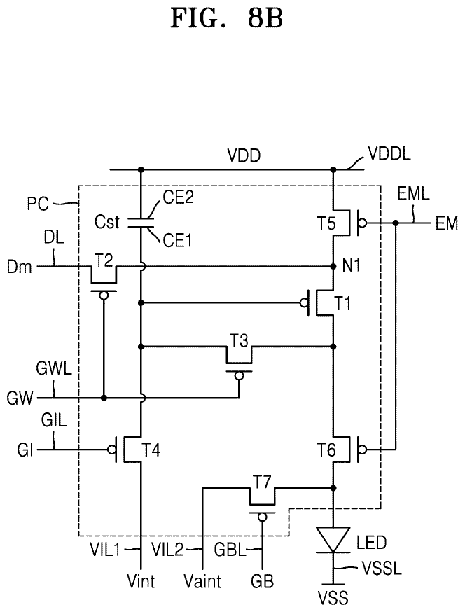

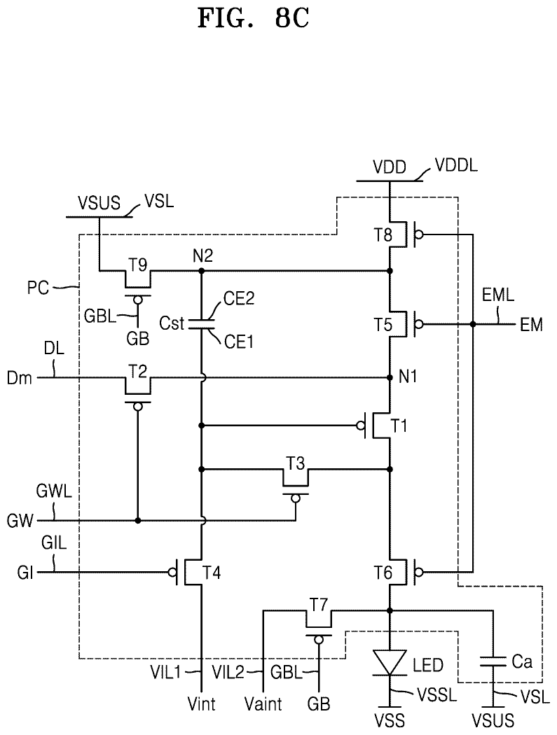

FIGS. 8A to 8C are equivalent circuit diagrams of a pixel of a display panel according to an embodiment.

Referring to FIG. 8A, the light-emitting diode LED corresponding to the pixel may be electrically connected to a pixel circuit PC. The pixel circuit PC may include a first transistor T1, a second transistor T2, and a storage capacitor Cst. The pixel circuit PC may be electrically connected to a signal line and a voltage line. The signal line may include a scan signal line GWL and a data line DL, and the voltage line may include a first voltage line VDDL.

The second transistor T2, which is a data write transistor, may be electrically connected to the scan signal line GWL and the data line DL. The scan signal line GWL may provide a scan signal GW to a gate electrode of the second transistor T2. The second transistor T2 may transfer a data signal Dm received via the data line DL to the first transistor T1 in response to the scan signal GW received via the scan signal line GWL.

The storage capacitor Cst may be electrically connected to the second transistor T2 and the first voltage line VDDL, and may store a voltage corresponding to a voltage difference between a voltage received from the second transistor T2 and a first power voltage VDD supplied via the first voltage line VDDL.

The first transistor T1, which is a driving transistor, may control a driving current which flows through the light-emitting diode LED. The first transistor T1 may be connected to the first voltage line VDDL and the storage capacitor Cst. The first transistor T1 may control a driving current from the first voltage line VDDL to the light-emitting diode LED in response to a value of the voltage stored in the storage capacitor Cst. The light-emitting diode LED may emit light with a certain luminance according to the driving current. A first electrode of the light-emitting diode LED may be electrically connected to the first transistor T1, and a second electrode of the light-emitting diode LED may be electrically connected to a second voltage line VSSL which supplies a second power voltage VSS.

In FIG. 8A, the pixel circuit PC includes one switching transistor (e.g., the second transistor T2) and one capacitor (e.g., the storage capacitor Cst). However, in another embodiment, the pixel circuit PC may include two or more switching transistors and/or two or more capacitors.

Referring to FIG. 8B, the pixel circuit PC may include the first transistor T1, the second transistor T2, a third transistor T3, a fourth transistor T4, a fifth transistor T5, a sixth transistor T6, a seventh transistor T7, and the storage capacitor Cst. The first transistor T1 may be a driving transistor, and the second transistor T2, the third transistor T3, the fourth transistor T4, the fifth transistor T5, the sixth transistor T6, and the seventh transistor T7 may be switching transistors.

The pixel circuit PC may be electrically connected to signal lines and voltage lines. The signal lines may include gate lines, such as, for example, the scan signal line GWL, a bypass control line GBL, an initialization control line GIL, and an emission control line EML, and the data line DL. The voltage lines may include a first initialization voltage line VIL1, a second initialization voltage line VIL2, and the first voltage line VDDL.

The first voltage line VDDL may transfer the first power voltage VDD to the first transistor T1. The first initialization voltage line VIL1 may transfer, to the pixel circuit PC, a first initialization voltage Vint which initializes the first transistor T1. The second initialization voltage line VIL2 may transfer, to the pixel circuit PC, a second initialization voltage Vaint which initializes the first electrode of the light-emitting diode LED.

The first transistor T1 may be electrically connected to the first voltage line VDDL via the fifth transistor T5 and may be electrically connected to the light-emitting diode LED via the sixth transistor T6. The first transistor T1 may serve as a driving transistor, and may receive the data signal Dm according to a switching operation of the second transistor T2 and supply the driving current to the light-emitting diode LED.

The second transistor T2, which is a data write transistor, may be electrically connected to the scan signal line GWL and the data line DL. The second transistor T2 may be electrically connected to the first voltage line VDDL via the fifth transistor T5. The second transistor T2 may be turned on according to the scan signal GW received via the scan signal line GWL and may perform a switching operation for transferring the data signal Dm received via the data line DL to a first node N1.

The third transistor T3 may be electrically connected to the scan signal line GWL and may be electrically connected to the light-emitting diode LED via the sixth transistor T6. The third transistor T3 may be turned on according to the scan signal GW received via the scan signal line GWL and may diode-connect the first transistor T1.

The fourth transistor T4, which is a first initialization transistor, may be electrically connected to the initialization control line GIL and the first initialization voltage line VIL1. The fourth transistor T4 may be turned on according to an initialization control signal GI received via the initialization control line GIL, and may transfer the initialization control line GIL from the first initialization voltage line VIL1 to a gate electrode of the first transistor T1 and initialize a voltage of the gate electrode of the first transistor T1. The initialization control signal GI may correspond to a scan signal of another pixel circuit which is arranged in a previous row of the corresponding pixel circuit PC.

The fifth transistor T5 may be an operation control transistor and the sixth transistor T6 may be an emission control transistor. The fifth transistor T5 and the sixth transistor T6 may be electrically connected to the emission control line EML, and may be simultaneously turned on according to an emission control signal EM received via the emission control line EML and may form a current path such that the driving current may flow from the first voltage line VDDL toward the emission control line EML. The first electrode of the light-emitting diode LED may be electrically connected to the first transistor T1 via the sixth transistor T6, and the second electrode of the light-emitting diode LED may be electrically connected to the second voltage line VSSL which supplies the second power voltage VSS.

The seventh transistor T7, which is a second initialization transistor, may be electrically connected to the bypass control line GBL, the second initialization voltage line VIL2, and the sixth transistor T6. The seventh transistor T7 may be turned on according to a bypass control signal GB received via the bypass control line GBL, and may transfer the second initialization voltage Vaint from the second initialization voltage line VIL2 to the first electrode of the light-emitting diode LED, thereby initializing the first electrode of the light-emitting diode LED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may store and sustain a voltage corresponding to a voltage difference between opposite ends respectively connected to the first voltage line VDDL and the gate electrode of the first transistor T1, such that a voltage applied to the gate electrode of the first transistor T1 may be sustained.

Referring to FIG. 8C, the pixel circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca. The first transistor T1 may be a driving transistor, and the second transistor T2, the third transistor T3, the fourth transistor T4, the fifth transistor T5, the sixth transistor T6, the seventh transistor T7, the eighth transistor T8, and the ninth transistor T9 may be switching transistors.

The pixel circuit PC may be electrically connected to signal lines and voltage lines. The signal lines may include gate lines, such as, for example, the scan signal line GWL, the bypass control line GBL, the initialization control line GIL, and the emission control line EML, and the data line DL. The voltage lines may include the first initialization voltage line VIL1, the second initialization voltage line VIL2, a sustain voltage line VSL, and the first voltage line VDDL.

The first voltage line VDDL may transfer the first power voltage VDD to the first transistor T1. The first initialization voltage line VIL1 may transfer, to the pixel circuit PC, the first initialization voltage Vint which initializes the first transistor T1. The second initialization voltage line VIL2 may transfer, to the pixel circuit PC, the second initialization voltage Vaint which initializes the first electrode of the light-emitting diode LED. During an initialization period and a data write period, the sustain voltage line VSL may provide a sustain voltage VSUS to a second node N2, e.g., the second electrode CE2 of the storage capacitor Cst.

The first transistor T1 may be electrically connected to the first voltage line VDDL via the fifth transistor T5 and the eighth transistor T8, and may be electrically connected to the light-emitting diode LED via the sixth transistor T6. The first transistor T1 may serve as a driving transistor, and may receive the data signal Dm according to a switching operation of the second transistor T2 and supply the driving current to the light-emitting diode LED.

The second transistor T2 may be electrically connected to the scan signal line GWL and the data line DL and may be electrically connected to the first voltage line VDDL via the fifth transistor T5 and the eighth transistor T8. The second transistor T2 may be turned on according to the scan signal GW received via the scan signal line GWL and may perform a switching operation for transferring the data signal Dm received via the data line DL to the first node N1.

The third transistor T3 may be electrically connected to the scan signal line GWL and may be electrically connected to the light-emitting diode LED via the sixth transistor T6. The third transistor T3 may be turned on according to the scan signal GW received via the scan signal line GWL and may diode-connect the first transistor T1, thereby compensating for a threshold voltage of the first transistor T1.

The fourth transistor T4 may be electrically connected to the initialization control line GIL and the first initialization voltage line VIL1, and may be turned on according to the initialization control signal GI received via the initialization control line GIL and may transfer the first initialization voltage Vint from the first initialization voltage line VIL1 to the gate electrode of the first transistor T1 such that a voltage of the gate electrode of the first transistor T1 may be initialized. The initialization control signal GI may correspond to a scan signal of another pixel circuit which is arranged in a previous row of the corresponding pixel circuit PC.

The fifth transistor T5, the sixth transistor T6, and the eighth transistor T8 may be electrically connected to the emission control line EML, and may be simultaneously turned on according to the emission control signal EM received via the emission control line EML and may form a current path such that the driving current may flow from the first voltage line VDDL toward the emission control line EML. The first electrode of the light-emitting diode LED may be electrically connected to the first transistor T1 via the sixth transistor T6, and the second electrode of the light-emitting diode LED may be electrically connected to the second voltage line VSSL which supplies the second power voltage VSS.

The seventh transistor T7, which is a second initialization transistor, may be electrically connected to the bypass control line GBL, the second initialization voltage line VIL2, and the sixth transistor T6. The seventh transistor T7 may be turned on according to the bypass control signal GB received via the bypass control line GBL and may transfer the second initialization voltage Vaint from the second initialization voltage line VIL2 to the first electrode of the light-emitting diode LED, thereby initializing the first electrode of the light-emitting diode LED.

The ninth transistor T9 may be electrically connected to the bypass control line GBL, the second electrode CE2 of the storage capacitor Cst, and the sustain voltage line VSL. The ninth transistor T9 may be turned on according to the bypass control signal GB received via the bypass control line GBL and may transfer the sustain voltage VSUS to the second node N2, e.g., the second electrode CE2 of the storage capacitor Cst, during the initialization period and the data write period.

The eighth transistor T8 and the ninth transistor T9 may each be electrically connected to the second node N2, e.g., the second electrode CE2 of the storage capacitor Cst. In an embodiment, during the initialization period and the data write period, the eighth transistor T8 may be turned off and the ninth transistor T9 may be turned on, and during an emission period, the eighth transistor T8 may be turned on and the ninth transistor T9 may be turned off.

The storage capacitor Cst may include the first electrode CE1 and the second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the sustain voltage line VSL, and the first electrode of the light-emitting diode LED. The auxiliary capacitor Ca may be store and sustain a voltage corresponding to a voltage difference between the first electrode of the light-emitting diode LED and the sustain voltage line VSL while the seventh transistor T7 and the ninth transistor T9 are turned on, thereby preventing a problem of black luminance increasing when the sixth transistor T6 is turned off.

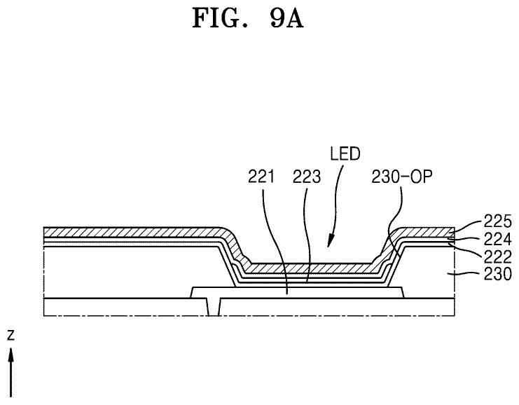

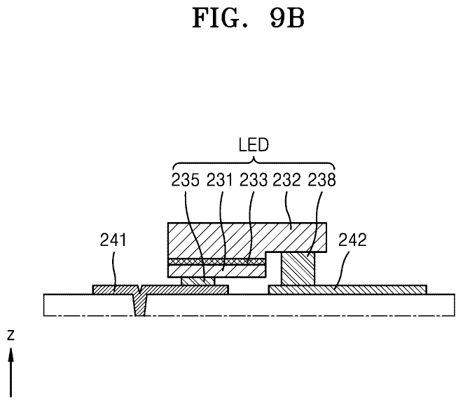

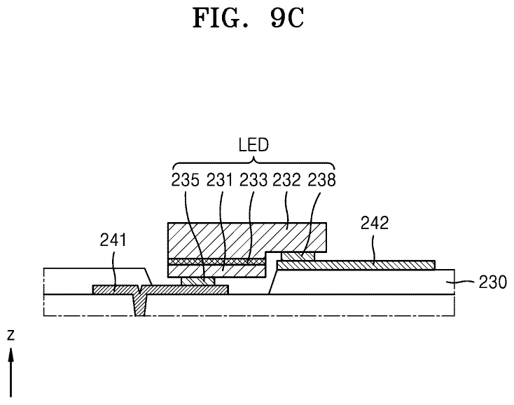

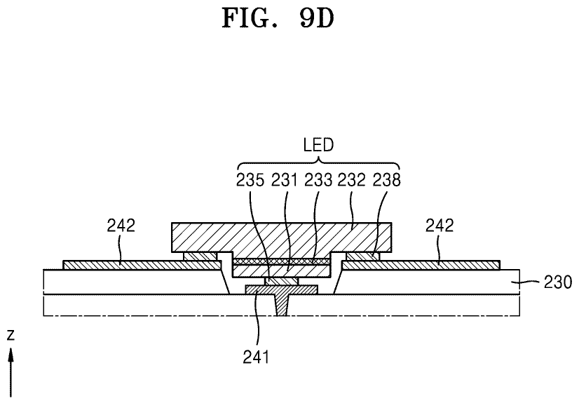

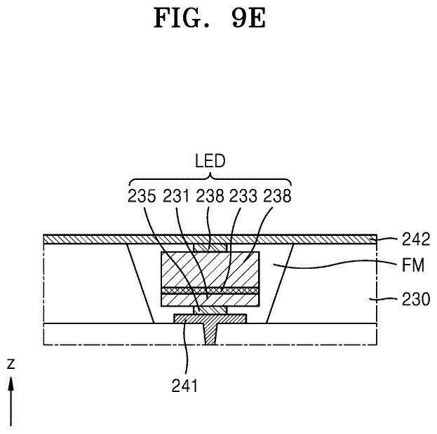

FIGS. 9A to 9E are each a cross-sectional view schematically illustrating a light-emitting diode of a display panel according to an embodiment.

Referring to FIG. 9A, the light-emitting diode LED according to an embodiment may include an organic light-emitting diode OLED which includes an organic material. The light-emitting diode LED may include a first electrode 221, a second electrode 225 which is opposite to the first electrode 221, and an emission layer 223 which is arranged between the first electrode 221 and the second electrode 225. A first functional layer 222 may be arranged between the first electrode 221 and the emission layer 223, and a second functional layer 224 may be arranged between the emission layer 223 and the second electrode 225.

An edge of the first electrode 221 may be covered by a bank layer 230 which includes an insulating material. The bank layer 230 may include an opening 230-OP which overlaps a central portion of the first electrode 221.

The first electrode 221 may include a conductive oxide, such as, for example, indium tin oxide (ITO), indium zinc oxide (IZO), zinc oxide (ZnO), indium oxide (In₂O₃), indium gallium oxide (IGO), or aluminum zinc oxide (AZO). In another embodiment, the first electrode 221 may include a reflective layer, including Ag, Mg, Al, Pt, Au, Ni, Nd, Ir, Cr, or a compound thereof. In another embodiment, the first electrode 221 may further include a layer which includes ITO, IZO, ZnO, AZO, or In₂O₃, above/below the reflective layer described herein.

The emission layer 223 may include a polymer or low-molecular weight organic material which emits light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material which has a low work function. For example, the second electrode 225 may include a (semi-)transparent layer which includes Ag, Mg, Al, Pt, Pd, Au, Ni, Nd, Ir, Cr, lithium (Li), Ca, or an alloy thereof. Alternatively, the second electrode 225 may further include a layer, such as, for example, ITO, IZO, ZnO, AZO, or In₂O₃, above the (semi-)transparent layer including the above-described materials.

Referring to FIG. 9B, the light-emitting diode LED may include an inorganic light-emitting diode iLED which includes an inorganic material. The light-emitting diode LED may include a first semiconductor layer 231, a second semiconductor layer 232, an intermediate layer 233 which is between the first semiconductor layer 231 and the second semiconductor layer 232, a first electrode 235 which is electrically connected to the first semiconductor layer 231, and a second electrode 238 which is electrically connected to the second semiconductor layer 232. The first electrode 235 and the second electrode 238 of the light-emitting diode LED may be electrically connected to a corresponding one of a first electrode pad 241 and a second electrode pad 242 which are arranged in a same layer. The second electrode pad 242 may be a portion of the second voltage line VSSL (see FIG. 4A), or may be a conductive layer electrically connected to the second voltage line VSSL (see FIG. 4A).

In some embodiments, the first semiconductor layer 231 may include a p-type semiconductor layer. The p-type semiconductor layer may be selected from among semiconductor materials having a composition formula of InxAlyGa1-x-yN (0≤x≤1, 0≤y≤1, 0≤x+y≤1), e.g., GaN, AlN, AlGaN, InGaN, InN, InAlGaN, or AlInN, and may be doped with a p-type dopant, such as, for example, Mg, Zn, Ca, strontium (Sr), or barium (Ba).

For example, the second semiconductor layer 232 may include an n-type semiconductor layer. The n-type semiconductor layer may be selected from among semiconductor materials having a composition formula of InxAlyGa1-x-yN (0≤x≤1, 0≤y≤1, 0≤(x+y)≤1), e.g., GaN, AlN, AlGaN, InGaN, InN, InAlGaN, or AlInN, and may be doped with an n-type dopant, such as, for example, silicon (Si), germanium (Ge), or tin (Sn).

The intermediate layer 233 is an area in which holes and electrons recombine, and as holes and electrons recombine, a transition may be made to a lower energy level, and light having the corresponding wavelength may be generated. The intermediate layer 233 may be formed to include a semiconductor layer having, for example, a composition formula of InxAlyGa1-x-yN (0≤x≤1, 0≤y≤1, 0≤(x+y)≤1), and may include a single quantum well structure or a multi quantum well (MQW) structure. In some aspects, a quantum wire structure or a quantum dot structure may be included.

In FIG. 9B, the first semiconductor layer 231 includes a p-type semiconductor layer and the second semiconductor layer 232 includes an n-type semiconductor layer. However, one or more embodiments are not limited thereto. In another embodiment, the first semiconductor layer 231 may include an n-type semiconductor layer and the second semiconductor layer 232 may include a p-type semiconductor layer.

In FIG. 9B, the first electrode pad 241 and the second electrode pad 242 are arranged in a same layer. However, one or more embodiments are not limited thereto. Referring to FIG. 9C, the first electrode pad 241 and the second electrode pad 242 may be arranged in different layers. For example, the bank layer 230 having defined therein an opening overlapping at least a portion of the first electrode pad 241 may be disposed on the first electrode pad 241, and the second electrode pad 242 may be disposed on an upper surface of the bank layer 230. The structure of the light-emitting diode LED illustrated in FIG. 9C is identical to the structure of the light-emitting diode LED described herein with reference to FIG. 9B.

In another embodiment, in a cross-sectional view, the second electrode pad 242 may be at opposite sides of the first electrode pad 241, as illustrated in FIG. 9D. The bank layer 230 may have defined therein an opening which overlaps at least a portion of the first electrode pad 241, and the second electrode pad 242 may be arranged around the opening defined in the bank layer 230. In some embodiments, in a plan view, the second electrode pad 242 may have a closed-loop shape which surrounds the opening defined in the bank layer 230 and/or the first electrode pad 241 entirely. The structure of the light-emitting diode LED illustrated in FIG. 9D is identical to the structure of the light-emitting diode LED described herein with reference to FIG. 9B.

In FIGS. 9B to 9D, the first electrode 235 and the second electrode 238 of the light-emitting diode LED face a same direction (e.g., a downward direction or the −z direction). However, one or more embodiments are not limited thereto. As illustrated in FIG. 9E, the first electrode 235 and the second electrode 238 of the light-emitting diode LED may face opposite directions.

The bank layer 230 may have defined therein an opening which exposes at least a portion of the first electrode pad 241, and a thickness of the bank layer 230 may be substantially equal to a thickness of the light-emitting diode LED. The opening defined in the bank layer 230 may be filled with a filling material FM, and the second electrode pad 242 may be disposed on the upper surface of the bank layer 230 and electrically connected to (e.g., in contact with) the second electrode 238 of the light-emitting diode LED. The filling material FM may include an organic material with insulating properties.

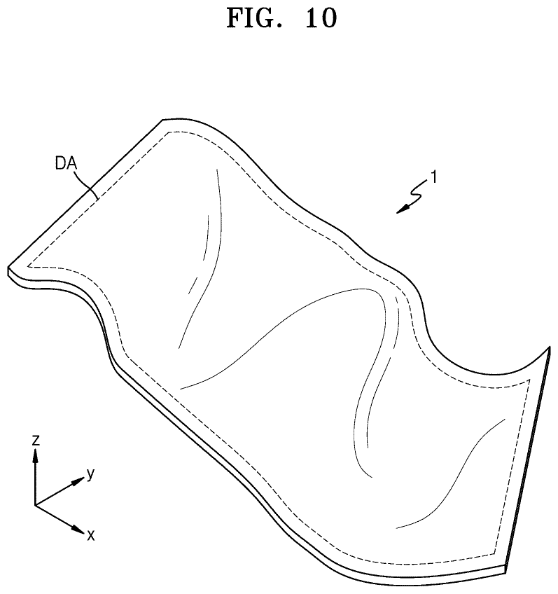

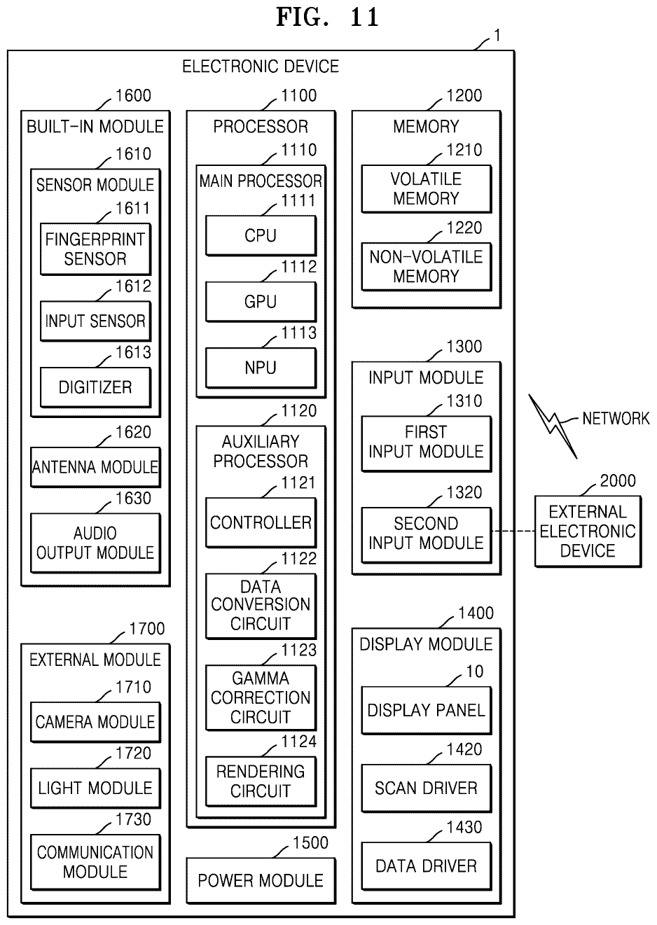

FIG. 10 is a perspective view schematically illustrating an embodiment of an electronic device 1 which includes a display panel, according to an embodiment. FIG. 11 is a block diagram illustrating the electronic device 1 which includes the display panel 10, according to an embodiment.

Referring to FIG. 10, the electronic device 1 may be freely deformed three-dimensionally and may provide a three-dimensional image surface through the display area DA. The electronic device 1 being freely deformed three-dimensionally is distinguished from an operation of an electronic device having a rollable display panel, in which while only a portion of a display area which is rolled is visible to a user, as another portion of the rolled display area is unrolled, the entire display area is visible to the user (or while the entire unrolled display area is visible to the user, as the display area is rolled, only a portion of the display area is visible to the user). The electronic device 1 according to one or more embodiments may be exhibit deformation such that an area of the entire display area DA increases or decreases again as the electronic device 1 is deformed in the x-direction, the y-direction, and/or the z-direction.

Referring to FIG. 11, the electronic device 1 may include a processor 1100, a memory 1200, an input module 1300, a display module 1400, a power module 1500, a built-in module 1600, and an external module 1700. According to an embodiment, in the electronic device 1, at least one of the elements described herein may be omitted, or one or more other elements may be added. According to an embodiment, some elements (e.g., the built-in module 1600) among the elements described herein may be integrated into another element (e.g., the display module 1400).

The processor 1100 may execute software to control at least one other element (e.g., a hardware or software element) of the electronic device 1 connected to the processor 1100 and perform various data processing or operations. According to an embodiment, as at least a part of data processing or operation, the processor 1100 may store, in a volatile memory 1210, commands or data received from another element (e.g., the input module 1300, a sensor module 1610, or a communication module 1730), and process the commands or data stored in the volatile memory 1210, and store resulting data in a non-volatile memory 1220.

The processor 1100 may include a main processor 1110 and an auxiliary processor 1120. The main processor 1110 may include at least one of a central processing unit (CPU) 1111 or an application processor (AP). The main processor 1110 may further include at least one of a graphics processing unit (GPU) 1112, a communication processor (CP), and an image signal processor (ISP). The main processor 1110 may further include a neural processing unit (NPU) 1113. The NPU is a processor specialized for processing an artificial intelligence model, and the artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-networks, or a combination of at least two of the list described herein. The artificial intelligence model may include, additionally or alternatively, a software structure, in addition to the hardware structure. At least one of the processing unit and the processor described herein may be implemented as a single integrated configuration (e.g., a single chip), or each of the two may be implemented as an independent configuration (e.g., a plurality of chips).

The auxiliary processor 1120 may include a controller 1121. The controller 1121 may include an interface conversion circuit and a timing control circuit. The controller 1121 may receive an image signal from the main processor 1110, convert a data format of the image signal to match interface specifications with the display module 1400, and output the image data. The controller 1121 may output various control signals for driving the display module 1400.

The auxiliary processor 1120 may further include a data processing unit, such as, for example, a data conversion circuit 1122, a gamma correction circuit 1123, or a rendering unit 1124. The data conversion circuit 1122 may receive image data from the controller 1121, compensate for the image data such that an image is displayed at a desired luminance according to characteristics of the electronic device 1 or user settings, or convert the image data to reduce power consumption or compensate for afterimages. The gamma correction circuit 1123 may convert image data or a gamma reference voltage such that an image displayed on the electronic device 1 has desired gamma characteristics. The rendering unit 1124 may receive the image data from the controller 1121, and render the image data by taking into consideration a pixel arrangement or the like of the display panel 10 applied to the electronic device 1. At least one of the data conversion circuit 1122, the gamma correction circuit 1123, or the rendering unit 1124 may be integrated into another element (e.g., the main processor 1110 or the controller 1121). In an embodiment, the auxiliary processor 1120 may be integrated into a data driver 1430.

The memory 1200 may store various data which is used by at least one element (e.g., the processor 1100 or the sensor module 1610) of the electronic device 1, or input data or output data for commands related to the at least one element. The memory 1200 may include at least one of the volatile memory 1210 or the non-volatile memory 1220.

The input module 1300 may receive, from the outside (e.g., a user or an external electronic device 2000)) of the electronic device 1, commands or data for use in an element (e.g., the processor 1100, the sensor module 1610, or an audio output module 1630) of the electronic device 1.

The input module 1300 may include a first input module 1310 which receives commands or data from a user, and a second input module 1320 which receives commands or data from the external electronic device 2000.

The first input module 1310 may include a microphone, a mouse, a keyboard, or a pen (e.g., a passive pen or an active pen). The first input module 1310 may include a mechanical input means, such as, for example, a button positioned on a rear surface or side surface of the electronic device 1, a dome switch, a jog wheel, or a jog switch, or a touch input means. The touch input means may include a touchscreen layer of the display panel 10.

The second input module 1320 may be connect, via wire or wirelessly, to the various types of external electronic devices 2000 connected to the electronic device 1. According to an embodiment, the second input module 1320 may include a high definition multimedia interface (HDMI), a universal serial bus (USB) interface, a Secure Digital (SD) card interface, or an audio interface. The second input module 1320 may include a connector which is capable of physically connecting the electronic device 1 to the external electronic device 2000, e.g., an HDMI connector, a USB connector, a SD card connector, or an audio connector (e.g., a headphone connector). In response to the external electronic device 2000 being connected to the second input module 1320, the electronic device 1 may perform an appropriate control related to the connected external electronic device 2000.

The display module 1400 ma provide information visually to a user. The display module 1400 may include the display panel 10, a scan driver 1420, and the data driver 1430.

The display panel 10 may display (output) information processed in the electronic device 1. The display panel 10 may display execution screen information of an application running in the electronic device 1, or user interface (UI), graphic user interface (GUI) information according to the execution screen information.

The scan driver 1420 may be mounted in the display panel 10 as a driving chip. In some embodiments, the scan driver 1420 may be formed directly on the display panel 10. For example, the scan driver 1420 may include an amorphous silicon TFT gate driver circuit (ASG), a low temperature polycrystalline silicon (LTPS), or an oxide semiconductor TFT gate driver circuit (OSG). The scan driver 1420 may receive a control signal from the controller 1121, and output scan signals to the display panel 10 in response to the control signal.

The display panel 10 may further include an emission control driver. The emission driver may output an emission control signal to the display panel 10 in response to a control signal received from the controller 1121. The emission control driver may be formed distinguished from the scan driver 1420, or may be integrated into the scan driver 1420.

The data driver 1430 may receive a control signal from the controller 1121, convert image data into a data voltage in an analog voltage form in response to the control signal, and then output data voltages to the display panel 10.

The data driver 1430 may be integrated into some configurations of the auxiliary processor 1120. For example, the data driver 1430 may be provided as a timing controller embedded driver integrated circuit (IC) which includes the controller 1121.

The power module 1500 may supply power to elements of the electronic device 1. The power module 1500 may include a battery 80 which charges a power voltage. In some aspects, the power module 1500 may include a connection port, and the connection port may be included in the second input module 1320 to which an external charger for supplying power for charging the battery 80 is connected. In some embodiments, the power module 1500 may include a wireless power transmission/reception member supportive of charging the battery 80 wirelessly. The wireless power transmission/reception member may include a plurality of coil-shaped antenna radiators. The power module 1500 may include a power management integrated circuit (PMIC). The PMIC may supply optimized power to each of elements of the electronic device 1.

The electronic device 1 may further include the built-in module 1600 and the external module 1700. The built-in module 1600 may include the sensor module 1610, an antenna module 1620, and the audio output module 1630. The external module 1700 may include a camera module 1710, a light module 1720, and/or the communication module 1730.

The sensor module 1610 may include touch electrodes of the touchscreen layer and a touch sensor driving unit of the display panel 10. The sensor module 1610 may detect an input by a user's body or an input by a pen, and generate an electric signal or data value corresponding to the input. The sensor module 1610 may include at least one of a fingerprint sensor 1611, an input sensor 1612, or a digitizer 1613.

The fingerprint sensor 1611 may generate a data value corresponding to user's fingerprint. The fingerprint sensor 1611 may include either an optical or capacitive fingerprint sensor.

The input sensor 1612 may generate a data value corresponding to coordinate information of an input by a user's body or an input by a pen. The input sensor 1612 may generate a data value based on a change in electrostatic capacitance due to an input. The input sensor 1612 may detect an input by a passive pen or transmit/receive data to/from an active pen.

The input sensor 1612 may measure biometric signals, such as, for example, blood pressure, moisture, or body fat. In an example in which a user touches a part of his or her body to a sensor layer or a sensing panel and does not move for a certain period of time, the input sensor 1612 may detect a biometric signal based on a change in an electric field caused by the part of his or her body and output information desired by the user to the display module 1400.

The digitizer 1613 may generate a data value corresponding to coordinate information of an input by a pen. The digitizer 1613 may generate a data value based on an electromagnetic change caused by the input. The digitizer 1613 may detect an input by a passive pen or transmit/receive data to/from an active pen.

In an embodiment, at least one of the fingerprint sensor 1611, the input sensor 1612, or the digitizer 1613 may be embedded in the display panel 10. For example, at least one of the fingerprint sensor 1611, the input sensor 1612, or the digitizer 1613 may be formed through a process which is continuous with a process of forming pixel circuits and light-emitting diodes of the display panel 10. Due to at least one of the least one of the fingerprint sensor 1611, the input sensor 1612, or the digitizer 1613, the display panel 10 may function as one of the input modules 1300 which provide an input interface between the electronic device 1 and the user, while also functioning as the display module 1400 which provides an output interface between the electronic device 1 and the user.

In an embodiment, at least two of the fingerprint sensor 1611, the input sensor 1612, or the digitizer 1613 may be formed to be integrated into one sensing panel through a same process. The sensing panel may be arranged between the display panel 10 and a window which is disposed in an upper portion of the display panel 10, but one or more embodiments are not limited thereto.

The antenna module 1620 may include one or more antennas for transmitting signals or power to the outside or receiving signals or power from the outside. According to an embodiment, the communication module 1730 may transmit signals to an external electronic device or receive signals from the external electronic device through an antenna suitable for a communication scheme. An antenna pattern of the antenna module 1620 may be integrated into a configuration (e.g., the display panel 10) of the display module 1400 or the input sensor 1612.

The audio output module 1630, which is a device for outputting audio signals to the outside of the electronic device 1, may output audio data which is received from the communication module 1730 in a call signal reception mode, a call mode or recording mode, a speech recognition mode, or a broadcast reception mode or stored in the memory 1200. The audio output module 1630 may output an audio signal related to a function performed in the electronic device 1 (e.g., a call signal reception sound, a message reception sound, or the like). The audio output module 1630 may include a receiver and a speaker. At least one of the receiver or the speaker may be an audio generation device which is attached to a lower portion of the display panel 10 to vibrate the display panel 10 and output sound. The audio generation device may be a piezoelectric element or piezoelectric actuator which contracts and expands in response to an electric signal, or an exciter which generates a magnetic force by using a voice coil and vibrates the display panel 10.

The camera module 1710 may capture still images and moving images. According to an embodiment, the camera module 1710 may include one or more lenses, image sensors, or image signal processors. The camera module 1710 may further include an infrared camera which is capable of measuring the presence or absence of a user, a user's position, a user's gaze, or the like.

The light module 1720 may output a signal to notify the occurrence of an event by using light from a light source, or provide light for image acquisition. Here, examples of the event occurrence may include receiving a message, receiving a call signal, missing a call, an alarm, a schedule reminder, receiving an e-mail, or notifying battery charge capacity information. The light module 1720 may include a light-emitting diode or a xenon lamp. The light module 1720 may emit light of one or more colors to a front surface or rear surface of the electronic device 1. The light module 1720 may be operate in conjunction with the camera module 1710 or independently.

The communication module 1730 may support establishment of a wired or wireless communication channel between the electronic device 1 and the external electronic device 2000, and the performance of communication through the established communication channel. The communication module 1730 may include one or all of a wireless communication module, such as, for example, a cellular communication module, a short-range wireless communication module, or a global navigation satellite system (GNSS) communication module, a local area network (LAN) communication module, or a wired communication module, such as, for example, a power line communication module. The communication module 1730 may transmit/receive wireless signals on the Internet by using at least one of Wireless LAN (WLAN), Wireless-Fidelity (Wi-Fi), Wi-Fi Direct, or Digital Living Network Alliance (DLNA) technologies. In some aspects, the communication module 1730 may support short-range communication by using at least one of Bluetooth™, Radio Frequency Identification (RFID), Infrared Data Association (IrDA), Ultra Wideband (UWB), ZigBee, Near Field Communication (NFC), Wi-Fi, Wi-Fi Direct, or Wireless USB technologies. The communication modules 1730 of various types described herein may be implemented as one chip or as separate chips.

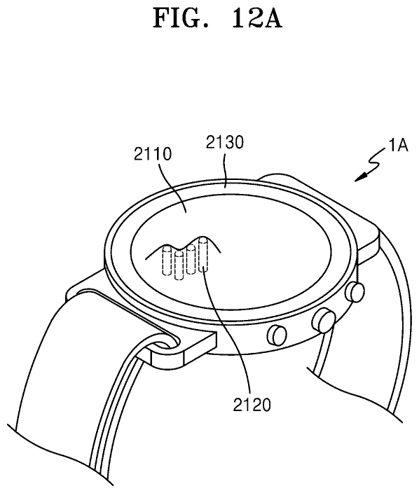

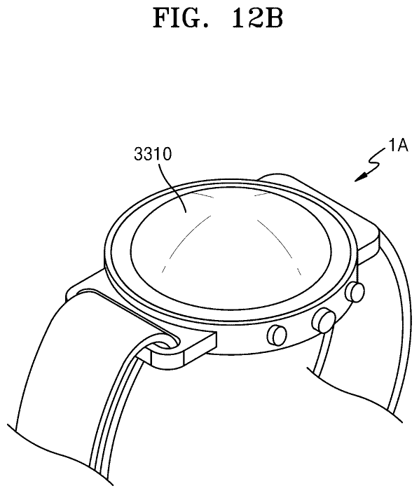

In the embodiment described with reference to FIGS. 10 and 11, the display panel 10 is included in the electronic device 1 which provides a three-dimensionally deformable image surface by being freely deformed three-dimensionally. However, one or more embodiments are not limited thereto. As illustrated in FIGS. 12A to 14, the electronic device may include an image providing area which has a fixed shape, and in a process of manufacturing the electronic device, a display panel may be arranged in the image providing area of the electronic device described herein, where the display panel may be fixed to the electronic device in a three-dimensionally deformed state.

FIGS. 12A to 14 are perspective views each illustrating an electronic device according to an embodiment. Electronic devices 1A, 1B, and 1C illustrated in FIGS. 12A to 14 may each include elements of the electronic device 1 described with reference to FIG. 11.

FIG. 12A show a smart watch as the electronic device 1A according to an embodiment. In an embodiment, a display unit 2110 of the smart watch may include the display panel described herein with reference to FIGS. 1 to 9E. In an embodiment, a display panel corresponding to the display unit 2110 is deformable three-dimensionally, and thus may provide various haptic information to a user. For example, haptic information or visual information may be provided to the user by a movement of a stroke 2120 arranged below the display unit 2110. In an embodiment, the display panel may be stretched three-dimensionally as the stroke 2120 moves in the third direction (e.g., the z direction or the −z direction), such that an image displayed on the display unit 2110 may be implemented to have a three-dimensional height. In some embodiments, haptic information (e.g., Braille information for the visually impaired) may be provided to the user through the display unit 2110 (or the display panel) while the stroke 2120 moves in the third direction (e.g., the z direction or the −z direction). The display panel and stroke 2120 corresponding to the display unit 2110 may be stored or assembled in a frame (or housing) 2130.

In FIG. 12A, the display unit 2110 has a dome shape in a state in which the display unit 2110 is not three-dimensionally stretched (e.g., an off state of the electronic device 1A). However, one or more embodiments are not limited thereto. In the state in which the display unit 2110 is not three-dimensionally stretched (e.g., the off state of the electronic device 1A), the display unit 2110 may be flat.

FIG. 12A illustrates a three-dimensionally stretchable smart watch, but one or more embodiments are not limited thereto. In another embodiment, because the display panel of the smart watch is three-dimensionally stretchable, the display panel may be three-dimensionally stretched along a body frame having a certain shape (e.g., a hemispherical shape) in a manufacturing process for the smart watch, and may be fixed and assembled to the body frame so as to form the display unit 2110 such that this display unit 2110 of the smart watch may not be three-dimensionally deformed.

FIG. 12B illustrates another embodiment of the smart watch as the electronic device 1A. The electronic device 1A illustrated in FIG. 12B may include a display unit 3310, and the display unit 3310 may have a three-dimensional dome shape (or hemispherical shape). A display device may be assembled on the dome-shaped body frame in a manufacturing process for the electronic device 1A, and in this case, because the display device is three-dimensionally stretchable, the display device may be assembled in a stretched state along a shape of the hemispherical body frame.

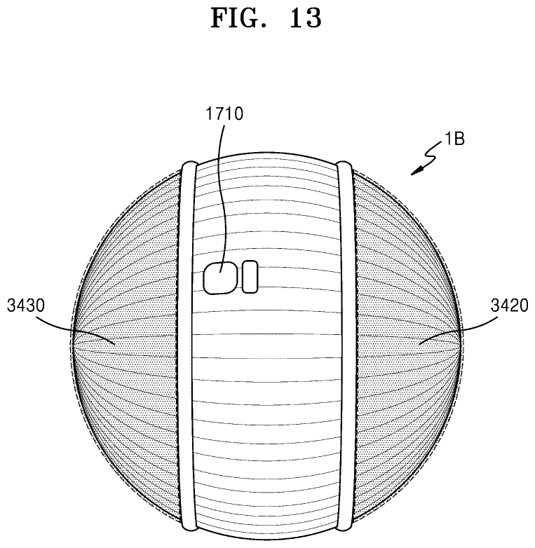

FIG. 13 illustrates a robot as the electronic device 1B according to an embodiment. The robot may recognize movement or objects by using the camera module 1710 and display a certain image to the user through display units 3420 and 3430. In some embodiments, display panels according to an embodiment may be stretched in various directions as described herein, and thus may be assembled to a frame of the electronic device 1B while being three-dimensionally stretched along a hemispherical shape to form the display units 3420 and 3430.

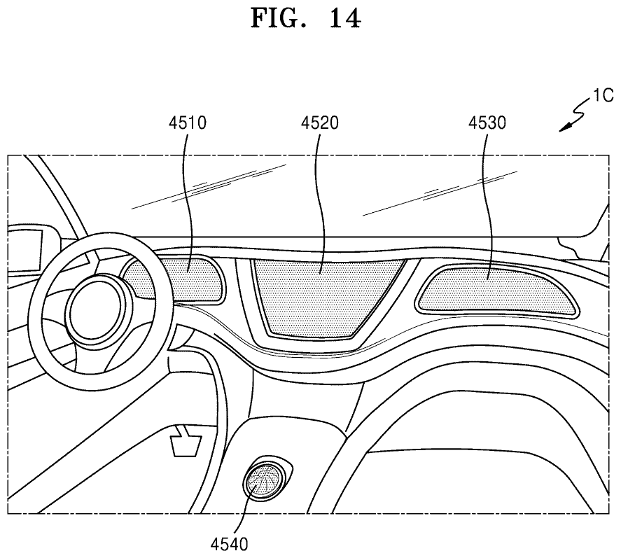

FIG. 14 illustrates a vehicle display device as an electronic device 1C according to an embodiment. The vehicle display device may include a cluster 4510, a center information display (CID) 4520, and/or a passenger display 4530. A display panel according to an embodiment may be stretched in various directions and thus, may be used for the cluster 4510, the CID 4520, and/or the passenger display 4530 regardless of a shape of an internal frame of the vehicle.

In FIG. 14, the cluster 4510, the CID 4520, and/or the passenger display 4530 are separated. However, one or more embodiments are not limited thereto. In another embodiment, at least two selected from among the cluster 4510, the CID 4520, and the passenger display 4530 may be integrally connected.

In some embodiments, the vehicle display device may include a button 4540 which is capable of displaying a certain image. The button 4540 having a hemispherical shape may sense a touch input of a user in the z-direction or the −z direction (e.g., a driver). In some embodiments, the button 4540 of FIG. 14 may include a stroke, as described herein with reference to FIG. 12A.

In FIGS. 12A, 12B, 13, and 14, the electronic devices 1A, 1B, and 1C are wearable devices which may be worn on a person's body, a robot, or an electronic device. However, one or more embodiments are not limited thereto. An electronic device according to an embodiment may include electronic devices for various purposes, such as, for example, commercial electronic devices, office electronic devices, educational electronic devices, wearable electronic devices, or medical electronic devices. In other words, a display panel according to an embodiment may be provided in any electronic device that includes an area capable of providing an image.

According to one or more embodiments, a display panel capable of implementing excellent quality images and being stretchable may be provided. The effects described herein are examples, and the effects of one or more embodiments are not limited to those described herein.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate comprising:
a first opening which is defined in the substrate and extends in a first direction; and
a second opening which is defined in the substrate and extends in a second direction crossing the first direction; and
a light-emitting diode disposed on the substrate,
wherein at least one of a first width of the first opening in the second direction or a second width of the second opening in the first direction ranges from about 6 micrometers to about 8 micrometers.

2. The display panel of claim 1, wherein the substrate comprises:
a plurality of first openings defined in the substrate;
a plurality of second openings defined in the substrate; and
a bridge portion between a first opening among the plurality of first openings and a second opening among the plurality of second openings.

3. The display panel of claim 2, wherein:
the bridge portion comprises a first bridge portion which extends in the first direction and a second bridge portion which extends in the second direction, and
at least one of a length of the first bridge portion in the first direction or a length of the second bridge portion in the second direction ranges from about 17 micrometers to about 25 micrometers.

4. The display panel of claim 1, wherein:
the substrate comprises an island portion which is partially surrounded by the first opening and the second opening, and
the light-emitting diode overlaps the island portion.

5. The display panel of claim 4, further comprising an inorganic insulating layer which is arranged between the substrate and the light-emitting diode and overlaps the island portion,
wherein a groove defined in the inorganic insulating layer overlaps the first opening or the second opening.

6. The display panel of claim 5, wherein:
the inorganic insulating layer has a shape which comprises a plurality of islands, and
the plurality of islands are spaced apart from each other by the groove.

7. The display panel of claim 5, wherein recesses defined in the inorganic insulating layer are adjacent to:
opposite ends of the first opening; and
opposite ends of the second opening.

8. The display panel of claim 1, wherein:
the first opening comprises an extension portion at one or more of a first end of the first opening and a second end of the first opening, wherein the second end is opposite the first end in the first direction, and
a width of the extension portion is greater than the first width.

9. The display panel of claim 1, wherein a width of an end of the first opening in the first direction is less than a width of a central portion of the first opening.

10. The display panel of claim 1, wherein the first opening has a shape in which a central portion of the first opening in the first direction is recessed in the second direction.

11. A display panel comprising:
a substrate comprising:
a plurality of first openings which are defined in the substrate and extend in a first direction;
a plurality of second openings which are defined in the substrate and extend in a second direction crossing the first direction; and
a plurality of island portions which are each partially surrounded by one or more first openings of the plurality of first openings and one or more second openings of the plurality of second openings; and
an inorganic insulating layer which is disposed on the substrate, wherein a groove defined in the inorganic insulating layer overlaps the plurality of first openings and the plurality of second openings,
wherein the inorganic insulating layer has a shape which comprises a plurality of islands, and the plurality of islands are spaced apart from each other by the groove and overlap the plurality of island portions of the substrate.

12. The display panel of claim 11, further comprising a plurality of light-emitting diodes which overlap each of the plurality of islands and are disposed on the substrate.

13. The display panel of claim 11, wherein at least one of a first width of a first opening of the plurality of first openings in the second direction or a second width of a second opening of the plurality of second openings in the first direction ranges from about 6 micrometers to about 8 micrometers.

14. The display panel of claim 11, wherein the substrate further comprises a bridge portion between a first opening among the plurality of first openings and a second opening among the plurality of second openings.

15. The display panel of claim 14, wherein:
the bridge portion comprises a first bridge portion which extends in a first direction and a second bridge portion which extends in a second direction, and
at least one of a length of the first bridge portion in the first direction or a length of the second bridge portion in the second direction ranges from about 17 micrometers to about 25 micrometers.

16. The display panel of claim 14, wherein at least some of the plurality of island portions of the substrate are connected to each other by the bridge portion.

17. The display panel of claim 11, wherein recesses defined in the inorganic insulating layer are adjacent to:
opposite ends of a first opening among the plurality of first openings; and
opposite ends of a second opening among the plurality of second openings.

18. The display panel of claim 11, wherein a second-direction width of a portion of a first opening among the plurality of first openings and a second-direction width of another portion of the first opening are different from one another.

19. The display panel of claim 18, wherein a width of a first opening included among the plurality of first openings with reference to the second direction changes along the first direction.

20. The display panel of claim 18, wherein:
the substrate comprises an extension portion at opposite ends of the first opening, and
a width of the extension portion is greater than a width of the first opening in the second direction.

21. An electronic device for providing an image, the electronic device comprising a display panel,
wherein the display panel comprises:
a substrate comprising:
a plurality of first openings which are defined in the substrate and extend in a first direction;
a plurality of second openings which are defined in the substrate and extend in a second direction crossing the first direction; and
a plurality of island portions which are each partially surrounded by one or more first openings of the plurality of first openings and one or more second openings of the plurality of second openings; and
an inorganic insulating layer which is disposed on the substrate, wherein a groove defined in the inorganic insulating layer overlaps the plurality of first openings and the plurality of second openings,
wherein the inorganic insulating layer has a shape which comprises a plurality of islands, and the plurality of islands are spaced apart from each other by the groove and overlap the plurality of island portions of the substrate.

22. An electronic device comprising:
a display unit;
a display panel corresponding to the display unit; and
a stroke which is disposed under the display panel and moves up and down,
wherein the display panel comprises:
a substrate comprising:
a plurality of first openings which extend in a first direction;
a plurality of second openings which extend in a second direction crossing the first direction; and
a plurality of island portions which are each partially surrounded by one or more first openings of the plurality of first openings and one or more second openings of the plurality of second openings; and
an inorganic insulating layer which is disposed on the substrate, wherein a groove defined in the inorganic insulating layer having overlaps the plurality of first openings and the plurality of second openings,
wherein the inorganic insulating layer has a shape which comprises a plurality of islands, and the plurality of islands are spaced apart from each other by the groove and overlap the plurality of island portions of the substrate.

23. The electronic device of claim 22, further comprising a frame in which the display panel and the stroke are accommodated.

24. The electronic device of claim 22, wherein the electronic device comprises a wearable electronic device.

25. The electronic device of claim 22, wherein the display panel is stretchable in three dimensions by the stroke.

26. The electronic device of claim 22, wherein the display unit has a dome shape in a state in which the display panel is not stretched in the three dimensions.
